(19) United States
(12) Patent Application Publication
(10) Pub. No.: US 2006/0118160 A1
(43) Pub. Date: Jun. 8, 2006

(54) Thermoelectric element and thermoelectric module

(75) Inventors: Ryoji Funahashi, Ikeda-shi (JP); Masashi Mikami, Ikeda-shi (JP); Toshiyuki Mihara, Ikeda-shi (JP); Saori Urata, Ikeda-shi (JP); Naoko Ando, Ikeda-shi (JP)

Correspondence Address: KNOBBE MARTENS OLSON & BEAR LLP, 2040 MAIN STREET, FOURTEENTH FLOOR, IRVINE, CA, 92614, US

(73) Assignee: NATIONAL INSTITUTE OF ADVANCED INDUSTRIAL SCIENCE AND TECHNOLOGY, Tokyo (JP)

(21) Appl. No.: 11/174,219

(22) Filed: Jul. 1, 2005

(30) Foreign Application Priority Data
Jul. 7, 2004 (JP) 2004-200207
Nov. 22, 2004 (JP) 2004-336809

(51) Int. Cl. H01L 35/28; H01L 35/12; H01L 35/14; H01L 35/20

(52) U.S. Cl. 136/236.1; 136/239; 136/212; 136/211

(57) ABSTRACT

The present invention provides a thermoelectric element comprising an electrically conductive substrate, a p-type thermoelectric material, and an n-type thermoelectric material; the p-type thermoelectric material being positioned on the substrate via an electrically conductive thermal buffer material, and the n-type thermoelectric material being positioned on the substrate via an electrically conductive thermal buffer material; wherein each thermoelectric material comprises a specific oxide and each electrically conductive thermal buffer material comprises an electrically conductive material having a thermal expansion coefficient between that of the thermoelectric material to which the thermal buffer material is bonded and that of the substrate. The invention also provides a thermoelectric module comprising a plurality of the thermoelectric elements. The thermoelectric element and the thermoelectric module have both a high thermoelectric conversion efficiency and excellent properties in terms of thermal stability, chemical durability, etc.

### TECHNICAL FIELD

The present invention relates to a thermoelectric element, a thermoelectric module, and a thermoelectric conversion method.

### BACKGROUND OF THE INVENTION

In Japan, only 30% of the primary energy supply is used as effective energy, with about 70% being eventually lost to the atmosphere as heat. The heat generated by combustion in industrial plants, garbage-incineration facilities and the like is lost to the atmosphere without conversion into other energy. In this way, we are wastefully discarding a vast amount of thermal energy, while acquiring only a small amount of energy by combustion of fossil fuels or other means.

To increase the proportion of energy to be utilized, the thermal energy currently lost to the atmosphere should be effectively used. For this purpose, thermoelectric conversion, which directly converts thermal energy to electrical energy, is an effective means. Thermoelectric conversion, which utilizes the Seebeck effect, is an energy conversion method for generating electricity by creating a difference in temperature between both ends of a thermoelectric material to produce a difference in electric potential.

In this thermoelectric generation, electricity is generated simply by setting one end of a thermoelectric material at a location heated to a high temperature by waste heat, and the other end in the atmosphere and connecting external resistances to both ends. This method entirely eliminates the need for moving parts such as the motors or turbines generally required for power generation. As a consequence, the method is economical and can be carried out without releasing the gases due to combustion. Moreover, the method can continuously generate electricity until the thermoelectric material has deteriorated. Furthermore, thermoelectric generation enables power generation at a high power density. Therefore, it is possible to make electric power generators (modules) small and light enough to use them as mobile power supplies for cellular phones, notebook computers, etc.

Therefore, thermoelectric generation is expected to play a role in the resolution of future energy problems. To realize thermoelectric generation, a thermoelectric module comprising a thermoelectric material that has both a high thermoelectric conversion efficiency and excellent properties in terms of heat resistance, chemical durability, etc., will be required.

CoO₂-based layered oxides such as Ca₃CO₄O₉ have been reported as substances that achieve excellent thermoelectric performance in air at high temperatures, and such thermoelectric materials are currently being developed (see R. Funahashi et al., Jpn. J. Appl. Phys., 39, L1127 (2000), for example).

However, the development of a thermoelectric module (electric power generator) that is needed to realize efficient thermoelectric generation using thermoelectric materials has been delayed so far. Therefore, in the power generation utilizing high-temperature heat, high thermal stress between components in a thermoelectric module composed of components of different kinds is caused due to a great temperature difference in the module, resulting in damaging the module.

### SUMMARY OF THE INVENTION

The present invention has been made to solve the above problems. A principal object of the invention is to provide a thermoelectric element and a thermoelectric module that have both a high thermoelectric conversion efficiency and excellent properties in terms of thermal stability, chemical durability, etc. that are required to realize thermoelectric generation.

The present inventors conducted extensive research to achieve the above object. As a result, the inventors found that a thermoelectric element having excellent properties can be obtained by connecting a p-type thermoelectric material and an n-type thermoelectric material each comprising a specific complex oxide to an electrically conductive substrate via an electrically conductive material having a thermal expansion coefficient between that of the thermoelectric material and that of the substrate. The thermoelectric element thus obtained has a high thermoelectric conversion efficiency and excellent electrical conductivity as well as excellent thermal stability, chemical durability, etc., and exhibits excellent properties as a thermoelectric element. The inventors also found that when a plurality of such thermoelectric elements are connected in series on an insulating substrate, a small thermoelectric module can be obtained with a high power density and excellent durability.

Specifically, the present invention provides the following thermoelectric element, thermoelectric module, and thermoelectric conversion method.

1. A thermoelectric element comprising an electrically conductive substrate, a p-type thermoelectric material, and an n-type thermoelectric material,

the p-type thermoelectric material being positioned on the substrate via an electrically conductive thermal buffer material, and the n-type thermoelectric material being positioned on the substrate via an electrically conductive thermal buffer material;

wherein the thermoelectric element meets requirements (i) to (iii):

(i) the p-type thermoelectric material comprises at least one complex oxide selected from the group consisting of complex oxides represented by the formula: CaₐA¹_{b}Co_{c}A²_{d}Oₑ (wherein A¹ is one or more elements selected from the group consisting of Na, K, Li, Ti, V, Cr, Mn, Fe, Ni, Cu, Zn, Pb, Sr, Ba, Al, Bi, Y, and lanthanoids; A² is one or more elements selected from the group consisting of Ti, V, Cr, Mn, Fe, Ni, Cu, Mo, W, Nb, and Ta; 2.2≦a≦3.6; 0≦b≦0.8; 2.0≦c≦4.5; 0≦d≦2.0; and 8≦e≦10) and complex oxides represented by the formula: Bi_{f}Pb_{g}M¹ₕCOᵢM²ⱼOₖ (wherein M¹ is one or more elements selected from the group consisting of Na, K, Li, Ti, V, Cr, Mn, Fe, Ni, Cu, Zn, Pb, Ca, Sr, Ba, Al, Y, and lanthanoids; M² is one or more elements selected from the group consisting of Ti, V, Cr, Mn, Fe, Ni, Cu, Mo, W, Nb, and Ta; 1.8≦f≦2.2; 0≦g≦0.4; 1.8≦h≦2.2; 1.6≦i≦2.2; 0≦j≦0.5; and 8≦k≦10);

(ii) the n-type thermoelectric material comprises at least one complex oxide selected from the group consisting of complex oxides represented by the formula: LnₘR¹ₙNiₚR²_{q}Oᵣ (wherein Ln is one or more elements selected from the group consisting of lanthanoids; R¹ is one or more elements selected from the group consisting of Na, K, Sr, Ca, and Bi; R² is one or more elements selected from the group consisting of Ti, V, Cr, Mn, Fe, Co, Cu, Mo, W, Nb, and Ta; 0.5≦m≦1.7; 0≦n≦0.5; 0.5≦p≦1.2; 0≦q≦0.5; and 2.7≦r≦3.3) and complex oxides represented by the formula: (LnₛR³ₜ)₂NiᵤR⁴ᵥO_{w} (wherein Ln is one or more elements selected from the group consisting of lanthanoids; R³ is one or more elements selected from the group consisting of Na, K, Sr, Ca, and Bi; R⁴ is one or more elements selected from the group consisting of Ti, V, Cr, Mn, Fe, Co, Cu, Mo, W, Nb, and Ta; 0.5≦s≦1.2; 0≦t≦0.5; 0.5≦u≦1.2; 0≦v≦0.5; and 3.6≦w≦4.4); and

(iii) each electrically conductive thermal buffer material comprises an electrically conductive material having a thermal expansion coefficient between the thermal expansion coefficient of the thermoelectric material to which the thermal buffer material is bonded and the thermal expansion coefficient of the substrate.

2. A thermoelectric element according to item 1, wherein each electrically conductive thermal buffer material comprises an oxide and a metal as effective components.

3. A thermoelectric element according to item 2, wherein the oxide in the electrically conductive thermal buffer material comprises all or some of the constituent elements of the thermoelectric material to which the thermal buffer material is bonded.

4. A thermoelectric element according to item 2 or 3, wherein each electrically conductive thermal buffer material comprises an oxide and a metal as effective components and has a graded composition in which the oxide/metal ratio varies gradually.

5. A thermoelectric element according to any one of items 1 to 4, wherein a net-like material or a fibrous material is provided at a junction between the electrically conductive substrate and each thermoelectric material.

6. A thermoelectric element according to any one of items 1 to 5, wherein the thermoelectric element has a thermoelectromotive force of at least 60 μv/K throughout the temperature range of 293 to 1073 K (absolute temperature).

7. A thermoelectric element according to any one of items 1 to 6, wherein the thermoelectric element has an electrical resistance of not more than 200 mΩ throughout the temperature range of 293 to 1073 K (absolute temperature).

8. A thermoelectric module comprising a plurality of thermoelectric elements according to any one of items 1 to 7, wherein the thermoelectric elements are electrically connected in series such that an unbonded end portion of a p-type thermoelectric material of one thermoelectric element is electrically connected to an unbonded end portion of an n-type thermoelectric material of another thermoelectric element.

9. A thermoelectric module according to item 8, wherein the unbonded end portions of the thermoelectric elements are connected on a substrate.

10. A thermoelectric module according to item 8 or 9, wherein the unbonded end portions of the thermoelectric elements are connected using an electrically conductive binder comprising an oxide and a metal.

11. A thermoelectric conversion method comprising positioning one end of a thermoelectric module according to any one of items 8 to 10 at a high-temperature part and positioning the other end of the module at a low-temperature part.

### BRIEF DESCRIPTION OF THE DRAWINGS

FIGS. 1 (I) and (II) are views each schematically showing the thermoelectric element according to one embodiment of the invention.

FIGS. 2 (I), (II), and (III) are views each schematically showing the thermoelectric element according to another embodiment of the invention.

FIG. 3 schematically shows a thermoelectric module using the thermoelectric elements of the invention.

FIG. 4 are scanning electron micrographs each showing a section of the junction of the substrate with the p-type thermoelectric material with regard to the thermoelectric element of Example 1 or the thermoelectric element of Comparative Example after being subjected to the heating and rapid cooling test.

FIG. 5 is a graph showing the temperature dependency of the internal resistance with regard to the thermoelectric elements of Example 1 and Comparative Example after being subjected to the heating and rapid cooling test.

In the drawings, each reference numeral denotes as follows: 1; insulating substrate, 2; electrically conductive layer, 3; thermal buffer material for p-type thermoelectric material, 4; thermal buffer material for n-type thermoelectric material, 5; p-type thermoelectric material, 6; n-type thermoelectric material, 7; metal sheet, and 8; net-like or fibrous material.

### DISCLOSURE OF THE INVENTION

The thermoelectric element of the present invention uses specific complex oxides for p-type and n-type thermoelectric materials, which are each bonded to an electrically conductive substrate via an electrically conductive thermal buffer material. The thermoelectric element of the present invention is described below in detail.

p-Type Thermoelectric Material

The p-type thermoelectric material comprises at least one oxide selected from the group consisting of complex oxides represented by the formula: CaₐA¹_{b}Co_{c}A²_{d}Oₑ (wherein Al is one or more elements selected from the group consisting of Na, K, Li, Ti, V, Cr, Mn, Fe, Ni, Cu, Zn, Pb, Sr, Ba, Al, Bi, Y, and lanthanoids; A² is one or more elements selected from the group consisting of Ti, V, Cr, Mn, Fe, Ni, Cu, Mo, W, Nb, and Ta; 2.2≦a≦3.6; 0≦b≦0.8; 2.0≦c≦4.5; 0≦d≦2.0; and 8≦e≦10) and complex oxides represented by the formula: Bi_{f}Pb_{g}M¹ₕCOᵢM²ⱼOₖ (wherein M¹ is one or more elements selected from the group consisting of Na, K, Li, Ti, V, Cr, Mn, Fe, Ni, Cu, Zn, Pb, Ca, Sr, Ba, Al, Y, and lanthanoids; M² is one or more elements selected from the group consisting of Ti, V, Cr, Mn, Fe, Ni, Cu, Mo, W, Nb, and Ta; 1.8≦f≦2.2; 0≦g≦0.4; 1.8≦h≦2.2; 1.6≦i≦2.2; 0≦j≦0.5; and 8≦k≦10). In the above formulae, examples of lanthanoids are La, Ce, Pr, Nd, Sm, Eu, Gd, Tb, Dy, Ho, Er, Tm, Lu, etc.

The complex oxides represented by the above formulae have a laminated structure with alternating rock-salt structure layers and CoO₂ layers, wherein the rock-salt structure layers have the components Ca, Co, and O in the ratio of Ca₂CoO₃, or the components Bi, M¹, and O in the ratio of Bi₂M¹₂O₄; and the CoO₂ layers have octahedrons with octahedral coordination of six O to one Co, the octahedrons being arranged two-dimensionally such that they share one another's sides. In the former case, some of the Ca in Ca₂CoO₃ is substituted by A¹, and some of the Co of this layer and some of the Co of the CoO₂ layer are further substituted by A². In the latter case, some of the Bi is substituted by Pb or some of M¹, and some of the Co is substituted by M².

Such complex oxides have high Seebeck coefficients as p-type thermoelectric materials and excellent electrical conductivity. For example, they have a Seebeck coefficient of at least about 100 μV/K and an electrical resistivity of not more than about 30 mωcm at temperatures of 100 K or more; and the Seebeck coefficient tends to increase and the electrical resistivity tends to decrease as the temperature rises.

The complex oxides represented by the above formulae may be in the form of single crystals or sintered polycrystals.

There are no limitations on the method for producing such complex oxides as long as a single crystal or a sintered polycrystal having the above-mentioned composition can be produced.

Crystal-structured complex oxides having the above-specified composition may be produced by known methods. Examples of known methods include single crystal-producing methods such as flux methods, zone-melting methods, crystal pulling methods, glass annealing methods via glass precursor, and the like; powder-producing methods such as solid phase reaction methods, sol-gel methods, and the like; film-forming methods such as sputtering methods, laser ablation methods, chemical vapor deposition methods, and the like; etc.

A process for preparing the complex oxide of the present invention according to a solid phase reaction method is described below as an example.

The complex oxide of the present invention can be produced by, for example, mixing starting materials in the same proportions as the proportions of the elemental components of the desired complex oxide, and sintering.

The sintering temperature and the sintering time are not limited as long as the desired complex oxide can be obtained. For example, sintering may be conducted at about 1073 to about 1373 K (absolute temperature) for about 20 to about 40 hours. When carbonates, organic compounds or the like are used as starting materials, the starting materials are preferably decomposed by calcination prior to sintering, and then sintered to give the desired complex oxide. For example, when carbonates are used as starting materials, they may be calcined at about 1073 to about 1173 K (absolute temperature) for about 10 hours, and then sintered under the above-mentioned conditions. Sintering means are not limited, and any means, including electric furnaces and gas furnaces, may be used. Usually, sintering may be conducted in an oxidizing atmosphere such as in an oxygen stream or air. When the starting materials contain a sufficient amount of oxygen, sintering in an inert atmosphere, for example, is also possible. The amount of oxygen in a complex oxide to be produced can be controlled by adjusting the partial pressure of oxygen during sintering, sintering temperature, sintering time, etc. The higher the partial pressure of oxygen is, the higher the oxygen ratio in the above formulae can be.

In the glass annealing method via glass precursor, starting materials are first melted and rapidly cooled for solidification. Any melting conditions can be employed as long as the starting materials can be uniformly melted. When a crucible of alumina is used as a vessel for melting operation, it is desirable to heat the starting materials to about 1473 to about 1673 K (absolute temperature) to prevent contamination with the vessel and to inhibit vaporization of the starting materials. The heating time is not limited, and the heating is continued until a uniform melt is obtained. The heating time is usually about 30 minutes to about 1 hour. The heating means are not limited, and any heating means can be employed, including electric furnaces, gas furnaces, etc. The melting can be conducted, for example, in an oxygen-containing atmosphere such as air or an oxygen stream adjusted to a flow rate of about 300 ml/min or less. In the case of starting materials containing a sufficient amount of oxygen, the melting may be conducted in an inert atmosphere.

The rapid cooling conditions are not limited. The cooling may be conducted to the extent that at least the surface of the solidified product becomes a glassy amorphous layer. For example, the melt can be rapidly cooled by allowing the melt to flow over a metal plate and compressing the same from above. The cooling rate is usually about 500° C./sec or greater, and preferably 10³° C./sec or greater.

Subsequently, the product solidified by rapid cooling is heat-treated in an oxygen-containing atmosphere, whereby fibrous single crystals of the desired complex oxide grow from the surface of the solidified product.

The heat treatment temperature may be in the range of about 1153 to about 1203 K (absolute temperature). The heat treatment can be conducted in an oxygen-containing atmosphere such as in air or an oxygen stream. When the heat treatment is effected in an oxygen stream, the stream may be adjusted to a flow rate of, for example, about 300 ml/min or less. The heat treatment time is not limited and can be determined according to the intended degree of growth of the single crystal. The heat treatment time is usually about 60 to about 1000 hours.

The mixing ratio of the starting materials can be determined depending on the chemical composition of the desired complex oxide. More specifically, when a fibrous complex oxide single crystal is formed from the amorphous layer of the surface of the solidified product, the oxide single crystal that grows has the composition of the solid phase in phase equilibrium with the amorphous layer, which is considered a liquid phase, of the surface part of the solidified product. Therefore, the mixing ratio of the starting materials can be determined based on the relationship of the chemical compositions between the solid phase (single crystal) and the liquid phase (amorphous layer) in phase equilibrium state.

The size of the complex oxide single crystal thus obtained depends on the kind of starting materials, composition ratio, heat treatment conditions, and so on. The single crystal may be fibrous, for example, having a length of about 10 to about 1000 μm, a width of about 20 to about 200 μm, and a thickness of about 1 to about 5 μm.

In both the glass annealing method via glass precursor and the solid phase reaction method, the amount of oxygen contained in the obtained product can be controlled according to the flow rate of oxygen during heating. The higher the flow rate of oxygen is, the greater the amount of oxygen in the product can be. Variation in the amount of oxygen in the product does not seriously affect the electrical characteristics of the complex oxide.

The starting materials are not limited as long as they can produce oxides when sintered. Useful starting materials are metals, oxides, compounds (such as carbonates), etc. Examples of Ca sources include calcium oxide (CaO), calcium chloride (CaCl₂), calcium carbonate (CaCO₃), calcium nitrate (Ca(NO₃)₂), calcium hydroxide (Ca(OH)₂), alkoxides such as dimethoxy calcium (Ca(OCH₃)₂), diethoxy calcium (Ca(OC₂H₅)₂), dipropoxy calcium (Ca(OC₃H₇)₂), and the like, etc. Examples of Co sources include cobalt oxide (CoO, CO₂O₃, and CO₃O₄), cobalt chloride (COCl₂), cobalt carbonate (CoCO₃), cobalt nitrate (Co(NO₃)₂), cobalt hydroxide (Co(OH)₂), alkoxides such as dipropoxy cobalt (Co(OC₃H₇)₂), and the like, etc. Similarly, examples of usable sources of other elements are metals, oxides, chlorides, carbonates, nitrates, hydroxides, alkoxides, and the like. Compounds containing two or more constituent elements of the complex oxide are also usable.

n-Type Thermoelectric Material

The n-type thermoelectric material comprises at least one oxide selected from the group consisting of complex oxides represented by the formula: LnₘR¹ₙNiₚR²_{q}Oᵣ (wherein Ln is one or more elements selected from the group consisting of lanthanoids; R¹ is one or more elements selected from the group consisting of Na, K, Sr, Ca, and Bi; R² is one or more elements selected from the group consisting of Ti, V, Cr, Mn, Fe, Co, Cu, Mo, W, Nb, and Ta; 0.5≦m≦1.7; 0≦n≦0.5; 0.5≦p≦1.2; 0≦q≦0.5; and 2.7≦r≦3.3) and complex oxides represented by the formula: (LnₛR³ₜ)₂NiᵤR⁴ᵥO_{w} (wherein Ln is one or more elements selected from the group consisting of lanthanoids; R³ is one or more elements selected from the group consisting of Na, K, Sr, Ca, and Bi; R⁴ is one or more elements selected from the group consisting of Ti, V, Cr, Mn, Fe, Co, Cu, Mo, W, Nb, and Ta; 0.5≦s≦1.2; 0≦t≦0.5; 0.5≦u≦1.2; 0≦v≦0.5; and 3.6≦w≦4.4). In the above formulae, examples of lanthanoids are La, Ce, Pr, Nd, Sm, Eu, Gd, Tb, Dy, Ho, Er, Tm, Lu, etc. The range of m is 0.5≦m≦1.7, and preferably 0.5≦m≦1.2.

The complex oxides represented by the above formulae have a negative Seebeck coefficient and exhibit properties as n-type thermoelectric materials in that when a difference in temperature is created between both ends of the oxide material, the electric potential generated by the thermoelectromotive force is higher at the high-temperature side than at the low-temperature side. More specifically, the above complex oxides have a negative Seebeck coefficient at temperatures of 373 K or higher. For example, they may have a Seebeck coefficient of about −1 to about −20 μV/K at temperatures of 373 K or higher.

Furthermore, the above complex oxides have excellent electrical conductivity and low electrical resistivity, and, for example, may have an electrical resistivity of about 20 mωcm or less at temperatures of 373 K or higher.

The former of the above two kinds of complex oxides has a perovskite-type crystal structure, which is generally referred to as an ABO₃ structure. The latter of the above two kinds of complex oxides has a so-called layered perovskite-type crystal structure, which is generally referred to as an A₂BO₄ structure. In these complex oxides, some of Ln is substituted by R¹ or R³, and some of Ni is substituted by R² or R⁴.

Sintered polycrystals of the above complex oxides can be prepared by mixing the starting materials in such a proportion as to have the same metal component ratios as the desired complex oxide, followed by sintering. More specifically, the starting materials are mixed to have the same metal component ratio of Ln, R¹, R², R³, R⁴, and Ni as in the above formulae, and the resulting mixture is then sintered to provide the sintered polycrystals of the desired complex oxides.

The starting materials are not limited as long as they produce oxides when sintered. Examples of usable materials include metals, oxides, compounds (such as carbonates), etc. Examples of usable sources of La are lanthanum oxide (La₂O₃), lanthanum carbonate (La₂(CO₃)₃), lanthanum nitrate (La(NO₃)₃), lanthanum chloride (LaCl₃), lanthanum hydroxide (La(OH)₃), lanthanum alkoxides (such as trimethoxy lanthanum (La(OCH₃)₃), triethoxy lanthanum (La(OC₂H₅)₃), tripropoxy lanthanum (La(OC₃H₇)₃), and the like), etc. Examples of usable sources of Ni are nickel oxide (NiO), nickel nitrate (Ni(NO₃)₂), nickel chloride (NiCl₂), nickel hydroxide (Ni(OH)₂), nickel alkoxides (such as dimethoxy nickel (Ni(OCH₃)₂), diethoxy nickel (Ni(OC₂H₅)₂), dipropoxy nickel (Ni(OC₃H₇)₂), and the like) etc. Similarly, examples of usable sources of other elements are metals, oxides, chlorides, carbonates, nitrates, hydroxides, alkoxides, and the like. Compounds containing two or more constituent elements of the complex oxide are also usable.

The sintering temperature and the sintering time are not limited as long as the desired complex oxide can be obtained. For example, sintering may be conducted at about 1123 to about 1273 K (absolute temperature) for about 20 to about 40 hours. When carbonates, organic compounds or the like are used as starting materials, the starting materials are preferably decomposed by calcination prior to sintering, and then sintered to give the desired complex oxide. For example, when carbonates are used as starting materials, they may be calcined at about 873 to about 1073 K (absolute temperature) for about 10 hours, and then sintered under the above-mentioned conditions.

Sintering means are not limited, and any means, including electric furnaces and gas furnaces, may be used. Usually, sintering may be conducted in an oxidizing atmosphere such as in an oxygen stream or air. When the starting materials contain a sufficient amount of oxygen, sintering in an inert atmosphere, for example, is also possible.

The amount of oxygen in a complex oxide to be produced can be controlled by adjusting the partial pressure of oxygen during sintering, sintering temperature, sintering time, etc. The higher the partial pressure of oxygen is, the higher the oxygen ratio in the above formulae can be. Variation in the amount of oxygen in the product does not seriously affect the thermoelectric characteristics of the complex oxide.

The complex oxide may be produced as a single crystal by methods such as flux method, as in the case of the p-type thermoelectric material.

Electrically Conductive Thermal Buffer Material

The electrically conductive thermal buffer material used in the present invention is not limited as long as it has a thermal expansion coefficient between the thermal expansion coefficient of the thermoelectric material to be bonded and the thermal expansion coefficient of the electrically conductive substrate, and it exhibits excellent electrical conductivity. The thermoelectric material preferably has electrical conductivity such that the proportion of the resistance of the thermal buffer material in the total resistance of the thermoelectric element is about 50% or less, more preferably about 10% or less, and even more preferably about 5% or less.

The electrically conductive thermal buffer material preferably contains a mixture of oxide and metal as effective components. Electrically conductive oxides may be used as the oxide in such a mixture. Insulative oxides such as alumina and magnesia may also be used as all or part of the oxide component as long as the proportion of the resistance of the resulting thermal buffer material in the total resistance of the thermoelectric element is about 50% or less.

The kinds of constituent elements of the oxide(s) are not limited. When the thermoelectric element is used at high temperatures, it is preferable to use an oxide containing only the constituent element(s) of the thermoelectric material to be bonded in order to prevent any change in characteristics caused by a reaction between the thermal buffer material and thermoelectric material. In this case, it is not necessary to use an oxide containing all the constituent elements of the thermoelectric material, but an oxide containing all or part of the constituent elements of the thermoelectric material may be used. In particular, it is preferable to use a complex oxide having the same constituent elements as those of the thermoelectric material, and more preferable to use a complex oxide having the same proportion of the elements as that of the thermoelectric material. Such complex oxides are also suitable in that they have excellent electrical conductivity.

Any metal that has excellent electrical conductivity may be used as a metal for the above mixture. It is preferable to use noble metals such as silver, gold, and platinum; alloys containing such noble metals; etc., since these do not easily undergo deterioration at high temperature. The proportion of noble metal in such noble metal-containing alloys is preferably about 30% or more by weight, and more preferably about 70% or more by weight.

The oxide/metal mixing ratio varies depending on the kind of oxide and metal. The mixing ratio is not limited as long as it provides the electrically conductive thermal buffer material with a thermal expansion coefficient between the thermal expansion coefficient of the thermoelectric material to be bonded and the thermal expansion coefficient of the electrically conductive substrate, and exhibits excellent electrical conductivity. In particular, it is preferable to use a mixing ratio such that the electrical resistivity of the resulting thermal buffer material is about the same as or lower than the electrical resistivity of the thermoelectric material. The oxide/metal mixing ratio is usually set within a wide range of about 1:9 to about 9:1 (weight ratio).

Furthermore, in order to improve the bonding strength to thermoelectric material and electrically conductive substrate and to increase the relaxation action for thermal stress, the oxide/metal mixture may have a graded composition in which the mixing ratio gradually varies. Specifically, the electrically conductive thermal buffer material may have a multi-layered structure with gradually changing mixing ratios wherein the proportion of oxide increases toward the junction of the thermal buffer material and the thermoelectric material, and the proportion of metal increases toward the junction of the thermal buffer material and the electrically conductive substrate. An example of a multi-layered thermal buffer material may have a gradient of oxide/metal ratio (weight ratio) of 9:1, 8:2, 6:4, 4:6, 2:8, and 1:9 in that order from the thermoelectric material side.

Among methods for forming a thermal buffer material layer, which are mentioned later, the method using oxide powders and metal powders is not limited in the particle sizes of oxide powder and metal powder. The particle size of an oxide powder is preferably such that about 80% or more of the particles have a particle size of about 50 μm or less, and more preferably about 1 to about 10 μm. The particle size of a metal powder is preferably such that about 80% or more of the particles have a particle size of about 0.1 to about 30 m.

In addition, fibrous materials may be used as all or part of the oxide and metal. The relaxation action for thermal stress can be increased by incorporating such fibrous materials.

The shape of such fibrous materials is not limited. For example, a fibrous material may have a length of about 0.01 to about 5 mm, with the cross-section thereof being quadrilateral, each side being about 0.1 to about 300 μm, or the cross-section thereof being circular with a diameter of about 0.1 to about 300 μm.

Electrically Conductive Substrate

The electrically conductive substrate is not limited as long as it is of electrically conductive material to which the p-type thermoelectric material and an n-type thermoelectric material can be connected. For example, the substrate may be an electrically conductive metal substrate in the shape of a sheet or the like, a substrate with an electrically conductive layer on an insulative ceramics, etc.

In view of stability at high temperature, the electrically conductive metal substrate may be, for example, a metal sheet with a thickness of about 10 μm to about 3 mm, the sheet being formed of a noble metal such as silver, gold, platinum, etc.; a noble metal alloy containing about 30% or more by weight, and preferably about 70% or more by weight, of such noble metals; etc.

The insulative ceramics is preferably a material that does not oxidize in high-temperature air at about 1073 K. For example, a substrate formed of an oxide ceramics such as alumina may be used.

The electrically conductive layer formed on an insulative ceramics is not limited as long as it is not oxidized in high-temperature air and has low electrical resistance. The electrically conductive layer may be formed of, for example, noble metals such as silver, gold, platinum, etc.; noble metal alloys containing about 30% or more by weight, and preferably about 70% or more by weight, of such noble metals; etc. An electrically conductive layer can be formed by the method of forming a conductive coat on an insulative ceramics, the method of bonding a metal sheet to an insulative ceramics, etc. A conductive coat can be formed by, for example, the method of vapor deposition, the method of applying and baking a paste containing a metal component, etc. A suitable metal sheet may have, for example, a thickness of about 10 μm to about 3 mm. When bonding a metal sheet to an insulative ceramics, a bonding agent may be used to stably bond the metal sheet to the insulative ceramics even at high temperature. For example, a noble metal paste such as mentioned above may be used.

The length, width, thickness, etc., of the electrically conductive substrate may be suitably determined according to module size, electrical resistance, etc. In view of the thermal history of the thermoelectric element or the thermoelectric generation module, it is preferable that the thermal expansion coefficient of the electrically conductive substrate be close to the thermal expansion coefficient of the thermoelectric material. Moreover, in order to efficiently transfer heat from a heat source to the high-temperature part of a thermoelectric element and to efficiently release heat from the low-temperature part, it is desirable to choose a substrate made of material with high thermal conductivity or to make the substrate thin.

Thermoelectric Element

The thermoelectric element of the present invention is formed by connecting a p-type thermoelectric material and an n-type thermoelectric material to an electrically conductive substrate each via an electrically conductive thermal buffer material.

It is preferable to use the thermoelectric materials in combination such that the sum of the absolute values of the thermoelectromotive forces of the p-type thermoelectric material and the n-type thermoelectric material is, for example, at least about 60 μv/K, and more preferably at least about 100 μv/K, at all temperatures in the range of 293 to 1073 K (absolute temperature). It is also preferable that each of these thermoelectric materials have an electrical resistivity of not more than about 100 mωcm, more preferably not more than about 50 mωcm, and even more preferably not more than about 10 mωcm, at all temperatures in the range of 293 to 1073 K (absolute temperature).

The size, shape, etc., of the p-type thermoelectric material and the n-type thermoelectric material used in the thermoelectric element are not limited. They may be suitably determined according to the size, shape, etc., of the intended thermoelectric module such that the desired thermoelectric performance is achieved. Examples include rectangular solid-shaped materials having a length of about 100 μm to about 20 cm with each side being about 1 μm to about 10 cm in cross-section, cylindrical materials having a length of about 100 μm to about 20 cm with the diameter thereof being about 1 μm to about 10 cm in cross-section, etc.

There are no limitations on the method of connecting thermoelectric materials to an electrically conductive substrate via an electrically conductive thermal buffer material. Any method may be used as long as it connects these materials with sufficient strength.

A thermoelectric element wherein a p-type thermoelectric material and an n-type thermoelectric material are connected to an electrically conductive substrate each via a thermal buffer material can be obtained by, for example, forming a thermal buffer material layer at each junction between the electrically conductive substrate and each of the p-type thermoelectric material and the n-type thermoelectric material, and simultaneously sintering the thermoelectric materials, thermal buffer materials, and electrically conductive substrate.

Examples of methods for forming a thermal buffer material layer at a junction between an electrically conductive substrate and a thermoelectric material include: methods of press-molding a mixture of oxide powder and metal powder, and providing the press-molded mixture between a thermoelectric material and an electrically conductive substrate; methods of adding a resin component and a solvent component to oxide powder and metal powder to form a paste, evaporating the solvent component from the paste to form a film containing oxide powder and metal powder, and providing the film between a thermoelectric material and an electrically conductive substrate; methods of forming a thermal buffer material layer on a surface to be bonded of a thermoelectric material or electrically conductive substrate by a vapor phase deposition method such as laser ablation method, vacuum deposition method, etc.; and methods of applying a solution containing oxide powder and metal powder to a surface to be bonded of a thermoelectric material or electrically conductive substrate by methods such as brush coating, spin coating, spray coating, etc.

The above methods may also be employed to form a thermal buffer material layer wherein the oxide/metal mixing ratio varies gradually. For example, a thermal buffer material layer with a graded oxide/metal mixing ratio can be obtained by forming a plurality of films with different mixing ratios and laminating these films.

The desired thermoelectric element can be produced by forming a thermal buffer material layer on a surface to be bonded of a thermoelectric material or electrically conductive substrate in the above-described manner, and providing the electrically conductive substrate and thermoelectric material at a predetermined position, followed by heating for sintering. The heating conditions are not limited as long as the electrically conductive substrate, thermal buffer material, and thermoelectric material are sintered to obtain sufficient bonding strength. The heating temperature may be, for example, about 773 to about 1273 K. In order to enhance bonding strength, the heating may be conducted while applying pressure perpendicular to the bonding surface.

The heating atmosphere is not limited as long as the materials do not deteriorate in the atmosphere. For example, the heating may be conducted in an oxidizing atmosphere such as in air or an oxygen stream; in a non-oxidizing atmosphere such as in a vacuum or nitrogen gas; etc.

Furthermore, the oxide in the thermal buffer material may be formed by using materials from which the desired oxide can be formed by heat treatment, such as carbonates, chlorides, nitrates, hydroxides, alkoxides, etc., as materials for forming the thermal buffer material layer, and conducting a method such as mentioned above to form a thermal buffer material layer, followed by heat treatment. The reaction temperature is, for example, about 673 to about 1273 K (absolute temperature). In this case, the heat treatment to sinter the materials makes it possible to conduct both the formation of oxide and the bonding by sintering through one heat treatment.

The thickness of a thermal buffer material layer is not limited. It may be suitably determined according to the size, kind, etc., of the thermoelectric materials such that an excellent thermal buffer effect is achieved and sufficient electrical conductivity is maintained. The thickness of a thermal buffer material layer is preferably about 0.01% to about 20%, and more preferably about 0.1% to about 5%, relative to the thickness of the thermoelectric material.

Bonding conditions are set such that the proportion of the resistance of the junction in the total resistance of the thermoelectric element is preferably about 50% or less, more preferably about 10% or less, and even more preferably about 5% or less. It is preferable to use the bonding methods that maintain the following characteristics of the obtained elements: at all temperatures in the range of 293 to 1073 K (absolute temperature), the thermoelectromotive force of thermoelectric element is at least 60 μv/K, and the electrical resistance thereof is not more than 200 mΩ.

When forming a thermal buffer material layer with graded composition, the thickness of each constituent film for forming the thermal buffer material layer may be suitably determined according to the number of the films as long as the total thickness of the buffer layer meets the above conditions.

In addition to the thermal buffer material, a net-like material or a fibrous material may be provided at the junction between the electrically conductive substrate and each thermoelectric material. The use of a net-like material or a fibrous material leads to high bonding strength and enhances relaxation action for thermal stress.

The net-like material is not limited as long as it achieves high bonding strength and has excellent electrical conductivity. As in the metals used in the thermal buffer material, it is preferable to use metal nets formed of noble metals such as silver, gold, and platinum; alloys containing such noble metals; etc., since these do not easily undergo deterioration at high temperature. It is especially preferable to use the same metal as the metal component used in the thermal buffer material or the metal component of the surface of the electrically conductive substrate. Ceramic nets such as aluminum oxide (Al₂O₃), magnesium oxide (MgO), etc., may be used.

The net-like material may be, for example, about 10 to about 300 μm in wire diameter and about 10 to about 200 mesh/inch. The net-like material is not limited in shape, and may be, for example, the same in shape as the junction or smaller than the junction.

The fibrous materials that may be used in the thermal buffer material may also be used as fibrous materials at the junction.

There are no limitations on the positions at which a net-like material or fibrous material may be provided. They may be provided between an electrically conductive substrate and a thermal buffer material, between a thermal buffer material and a thermoelectric material, etc. Furthermore, when thermal buffer material layer comprises a plurality of constituent films, the net-like material or fibrous material may be provided between the films from which the thermal buffer material layer is formed. The net-like material or fibrous material thus provided further improves the relaxation effect for thermal stress. In particular, an effect of further improving bonding strength is obtained when a metal net-like material or a metal fibrous material is provided between the electrically conductive substrate and the thermal buffer material, or when a ceramic net-like material or a ceramic fibrous material is provided between the thermal buffer material and the thermoelectric material.

The thermoelectric element containing a net-like material or a fibrous material can be produced by sintering the net-like material or fibrous material provided at a predetermined position together with the other materials of the thermoelectric element according to an above-described method.

Hereafter, embodiments of the thermoelectric element of the invention are described with reference to drawings.

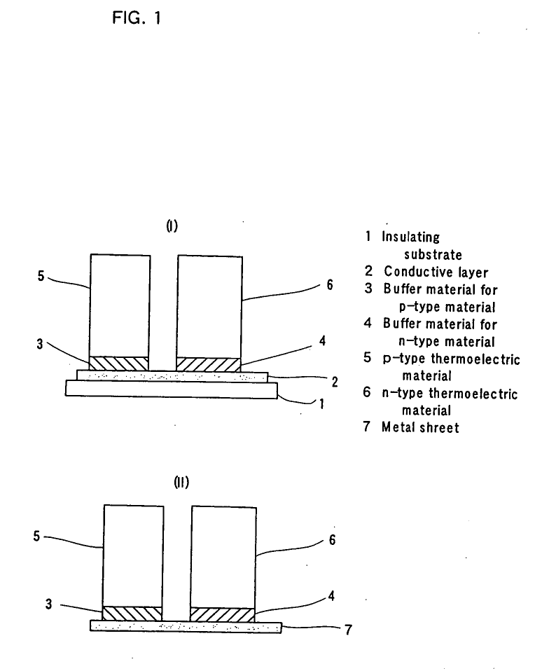

FIGS. 1 (I) and (II) are cross sectional views each schematically showing the thermoelectric element according to one embodiment of the invention which is configured such that thermal buffer layers are formed between an electrically conductive substrate and thermoelectric materials.

FIG. 1 (I) shows a thermoelectric element in which an electrically conductive substrate is obtained by forming an electrically conductive layer 2 on an insulating substrate 1, and a p-type thermoelectric material 5 and an n-type thermoelectric material 6 are bonded thereto via a thermal buffer material 3 for p-type thermoelectric material and via a thermal buffer material 4 for n-type thermoelectric material.

FIG. 1 (II) shows a thermoelectric element in which a metal sheet 7 serves as the electrically conductive substrate and a p-type thermoelectric material 5 and an n-type thermoelectric material 6 are bonded thereto via a thermal buffer material 3 for p-type thermoelectric material and via a thermal buffer material 4 for n-type thermoelectric material.

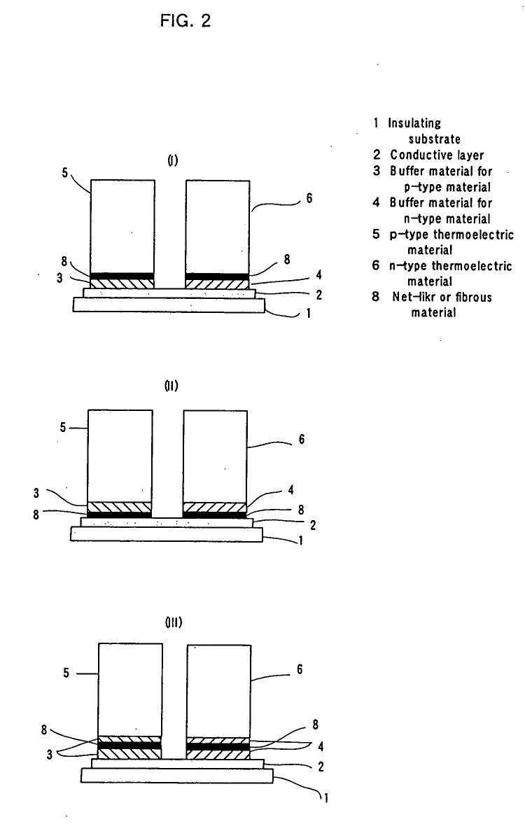

FIGS. 2 (I), (II), and (III) are cross sectional views each schematically showing the thermoelectric element according to another embodiment of the invention in which thermal buffer material layers and net-like or fibrous materials are interposed between thermoelectric materials and the electrically conductive substrate.

FIG. 2 (I) shows a thermoelectric element configured as follows: an electrically conductive substrate is obtained by forming an electrically conductive layer 2 on an insulating substrate 1; a thermal buffer material 3 for p-type thermoelectric material and a net-like or fibrous material 8 are laminated in that order at a junction with a p-type thermoelectric material 5; a thermal buffer material 4 for n-type thermoelectric material and a net-like or fibrous material 8 are laminated in that order at a junction with an n-type thermoelectric material 6; and each of the p-type thermoelectric material 5 and the n-type thermoelectric material 6 is bonded to the electrically conductive substrate via the respective laminates.

FIG. 2 (II) shows a thermoelectric element configured as follows: an electrically conductive substrate is obtained by forming an electrically conductive layer 2 on an insulating substrate 1; a net-like or fibrous material 8 and a thermal buffer material 3 for p-type thermoelectric material are laminated in that order on a junction with a p-type thermoelectric material 5; a net-like or fibrous material 8 and a thermal buffer material 4 for n-type thermoelectric material are laminated in that order at a junction with an n-type thermoelectric material 6; and each of the p-type thermoelectric material 5 and the n-type thermoelectric material 6 is bonded to the electrically conductive substrate via the respective laminates.

FIG. 2 (III) shows a thermoelectric element which is configured as follows: an electrically conductive substrate is obtained by forming an electrically conductive layer 2 on an insulating substrate 1; two films for forming a thermal buffer material 3 and two films for forming a thermal buffer material 4 are provided; a net-like or fibrous material 8 is interposed between the two films of the thermal buffer material 3 for p-type thermoelectric material, forming a laminate; a net-like or fibrous material 8 is interposed between the two films of the thermal buffer material 4 for n-type thermoelectric material, forming a laminate; and each of the p-type thermoelectric material 5 and the n-type thermoelectric material 6 is bonded to the electrically conductive substrate via the respective laminates

In the thermal buffer material layers shown in FIGS. 1 and 2, the mixing ratio of oxide to metal may be uniform. Alternatively, a graded structure may be employed wherein the oxide content is high at the junction with the thermoelectric material and the metal content is high at the junction with the electrically conductive substrate.

Thermoelectric Module

The thermoelectric module of the invention comprises a plurality of the above-described thermoelectric elements, wherein the thermoelectric elements are electrically connected in series such that an unbonded end portion of a p-type thermoelectric material of one thermoelectric element is electrically connected to an unbonded end portion of an n-type thermoelectric material of another thermoelectric element.

In general, on a substrate, the end portion of the p-type thermoelectric material of one thermoelectric element is electrically connected to the end portion of the n-type thermoelectric material of another thermoelectric element using an electrically conductive binder.

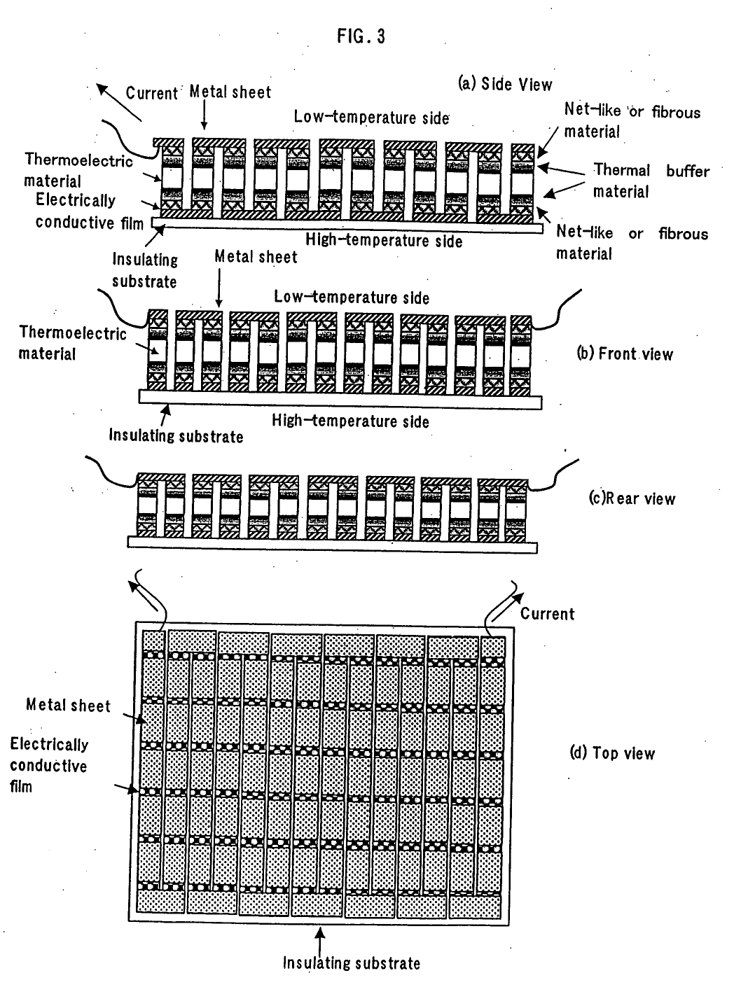

FIG. 3 schematically shows one embodiment of a thermoelectric module in which two or more of thermoelectric elements are electrically connected to one another using the binder on an insulating substrate. The thermoelectric module is configured such that electrically conductive films are formed on portions of the insulating substrate, to which thermoelectric elements are bonded, and the end portion of the p-type thermoelectric material of one thermoelectric element and the end portion of the n-type thermoelectric material of another thermoelectric element are connected on each of the electrically conductive films using the electrically conductive binder, thereby forming an electrical connection between the p-type thermoelectric material and the n-type thermoelectric material.

Each of the thermoelectric elements for use in the thermoelectric module shown in FIG. 3 has a configuration such that one end portion of the p-type thermoelectric material and one end portion of the n-type thermoelectric material are each bonded to the electrically conductive substrate composed of a metal sheet via a net-like material and a thermal buffer material. The themoelectric element is shaped as shown in FIG. 2 (II), wherein a metal sheet is used as the electrically conductive substrate.

The main purpose of using an insulating substrate for the thermoelectric module is to improve the uniform thermal properties and/or mechanical strength and to maintain electrically insulating properties, etc. The material characteristics of the substrate are not limited, and preferable is a material which does not melt and is not damaged at high temperatures of at least about 675 K, is chemically stable, is an electrically insulating material, does not react with the thermoelectric element or the binder, and has a favorable thermal conductivity. By using a highly thermally conductive substrate, the temperature of the high-temperature side of the element can be made approximately same as that of the high-temperature heat source, thereby generating a high voltage. Since the thermoelectric material used in the invention is an oxide, oxide ceramics, such as alumina, etc., are preferable as substrate materials considering thermal expansion, etc.

The electrically conductive film is formed at portions on the insulating substrate, to which the p-type thermoelectric material and the n-type thermoelectric material are bonded, and the electrically conductive film may be composed of noble metals, such as silver, gold, and platinum, or alloys containing about 30 wt % or more, preferably about 70 wt % or more of such noble metals. Such films can be formed by, for example, applying and baking pastes of these metals or conducting vapor deposition.

Any electrically conductive binder can be used insofar as it does not melt and maintains its chemical stability and low resistance at high temperature. For example, pastes, solders, etc. containing the noble metals, such as gold, silver, platinum, and alloys thereof, can be used. Thermal stress generated when the module is used at high temperatures can be reduced by using a binder containing an oxide and a metal as in the thermal buffer material for use in the production of the thermoelectric elements described above. In particular, the binder containing oxide and metal is preferable for disposing the insulating substrate at the high-temperature side when the thermoelectric module is used. In this case, as with the thermal buffer material, either an electrically conductive oxide or an insulating oxide may be used as the oxide contained in the binder and in particular, it is preferable to use an electrically conductive oxide comprising some or all of the elements constituting the thermoelectric material to be bonded to the insulating substrate. As with the thermal buffer material, noble metals, such as silver, gold, platinum, etc. and alloys containing such noble metals are preferable as the metal contained in the binder since deterioration does not easily occur at high temperature. The proportion of oxide to metal may be the same as in the thermal buffer material. Alternatively, a graded composition may likewise be employed as with the thermal buffer material, thereby further enhancing the reduction of thermal stress. The electrically conductivity of the electrically conductive binder may also be the same as that of the thermal buffer material.

As can be seen from the above, materials for the thermal buffer material described above can similarly be used for the electrically conductive binder, thereby effectively reducing the thermal stress generated at the junction of the thermoelectric element and the insulating substrate.

The binder containing oxide and metal can be positioned at the junction of the unbonded end portion of the thermoelectric element with the substrate in accordance with the following various processes in the same manner as in the production process for the thermal buffer material: a process of molding a mixture of oxide powder and metal powder under pressure and disposing the molded product between the unbonded end portion of the thermoelectric element and the electrically conductive film on the substrate; a process of further adding resin and a solvent to a mixture of oxide powder and metal powder to form a paste, evaporating the solvent from the paste to form a film containing oxide powder and metal powder, and disposing the obtained film between the unbonded end portion of the thermoelectric element and the electrically conductive film on the substrate; a process of forming a binder layer on the unbonded end portion of the thermoelectric element or the electrically conductive film on the substrate by a vapor phase deposition method, such as laser ablation, vacuum deposition, etc.; and a process of applying a solution containing oxide powder and metal powder to the unbonded end portion of the thermoelectric element or the electrically conductive film on the substrate by brush coating, spin coating, spraying, etc.

Furthermore, metallic fibers, oxide fibers, etc. may be added to the oxide and metal mixture, thereby further increasing the action of reducing thermal stress in the same manner as in the thermal buffer material.

By providing a net-like or fibrous material at the junction of the thermoelectric material and the electrically conductive film on the substrate, thermal stress can be further reduced.

Each of the thermoelectric elements is bonded to the insulating substrate by, for example, disposing each of the materials at predetermined positions of the substrate, and then sintering the materials under heat in the same manner as in the production process for the thermoelectric element.

The number of the thermoelectric elements used in one module is not limited, and can be suitably determined depending on the required electric power. FIG. 3 schematically shows the structure of the module produced using 84 thermoelectric elements. The output of the module is approximately equivalent to the value obtained by multiplying the output of each thermoelectric element by the number of the thermoelectric elements used.

The thermoelectric module of the invention may be provided with a heat insulating material at gaps among the plurality of thermoelectric elements disposed on the insulating substrate and gaps between the p-type thermoelectric material and the n-type thermoelectric material of each of the thermoelectric elements. Providing such a heat insulating material can suppress any elevation in temperature of the low-temperature side due to radiant heat produced from the high-temperature side of the substrate when the thermoelectric module is used, thereby increasing the thermoelectric conversion efficiency. There is no limitation to processes for providing such heat insulating materials, and heat insulating materials may be placed in the gaps between the thermoelectric elements after they are bonded to each other. According to a process comprising locating the heat insulating materials beforehand in accordance with the shape of the gaps on the insulating substrate, disposing each of the thermoelectric elements at a predetermined position, and then sintering them for bonding, the heat insulating materials can be efficiently disposed between the thermoelectric materials of each of the thermoelectric elements and bonding of the elements by sintering can be facilitated. The heat insulating materials with high temperature durability, such as, calcium silicate, porous alumina, etc. can be preferably used.

The thermoelectric module of the invention can produce a difference in electrical potential by positioning one end thereof at a high-temperature side and another end thereof at a low-temperature side, and can generate electrical energy by connecting external load thereto. For example, in the module of FIG. 3, a ceramic substrate is disposed at a high-temperature side and the other end is disposed at a low-temperature side. Note that the positioning manner of the thermoelectric module of the invention is not limited to the above, and all that is required is to position one end at a high-temperature side and the other end at a low-temperature side. For example, in the module of FIG. 3, the high-temperature side and the low-temperature side can be reversed.

Examples of heat sources for a high-temperature side include high-temperature heat of about 200° C. or higher generated in automobile engines; industrial plants, thermal power stations and atomic power stations; various fuel cells, such as molten carbonate fuel cells (MCFCs), hydrogen membrane fuel cells (HMFCs), and a solid oxide fuel cells (SOFCs); and various cogeneration systems, such as gas engine types, gas turbine types, and the like; and low-temperature heat of about 20° C. to about 200° C., such as solar heat, boiling water, body temperature, etc.

### EFFECT OF THE INVENTION

The present invention provide a thermoelectric element with high thermoelectric conversion efficiency as well as excellent thermal stability, chemical durability, etc. Since the present invention also provides various types of thermoelectric elements, an optimum thermoelectric element can be easily produced in accordance with the intended use, the production cost of the target thermoelectric module, and the like.

The thermoelectric module of the invention employing such thermoelectric elements is given excellent thermal resistance, and therefore it is not damaged and its electricity generation properties are not easily deteriorated even when the high-temperature side is rapidly cooled to room temperature from a high temperature of about 700° C.

As described above, due to the high thermal shock resistance, the thermoelectric module of the invention can achieve thermoelectric generation utilizing not only waste heat generated in industrial plants, garbage-incineration facilities, thermal power stations, atomic power stations, various fuel cells, cogeneration systems, etc. but also heat generated in automobile engines, in which prior-art thermoelectric modules are often damaged at the junction due to rapidly changing temperatures.

Moreover, since the thermoelectric module can generate electricity from heat energy of about 200° C. or lower, providing a heat source thereto allows the application thereof to a power supply which does not require recharging for use in portable equipment such as mobile phones, laptop computers, etc.

### EXAMPLES

Examples are given below to illustrate the invention in further detail.

### Example 1

(1) Production of p-Type Thermoelectric Material

Using calcium carbonate, bismuth oxide, and cobalt oxide as starting materials, these starting materials were mixed in such a manner as to yield the same element ratio as that of a complex oxide represented by the chemical formula: Ca_{2.7}Bi_{0.3}CO₄O_{9.3}. the mixture was calcined at 1073 K for 10 hours in the atmospheric pressure to give a calcinate. The calcinate was crushed and molded under pressure, and the molded body was sintered in a 300 ml/min oxygen stream at 1153 K for 20 hours. The sintered product was crushed and molded under pressure, and the molded body was hot-press sintered at 1123 K in air under uniaxial pressure of 10 Mpa for 20 hours, thereby producing a complex oxide for p-type thermoelectric material.

The complex oxide for p-type thermoelectric material obtained was cut and formed into a rectangular parallelepiped which has a surface of 4 mm×4 mm in parallel to the pressing axis during hot pressing and a length of 5 mm perpendicular to the pressing axis, thereby producing a p-type thermoelectric material.

(2) Production of n-Type Thermoelectric Material

Using nitrates of La, Bi, and Ni as starting materials, the starting materials were weighed in such a manner as to have the same element ratio as that of the complex oxide represented by the chemical formula: La_{0.9}Bi_{0.1}NiO_{3.0}, and dissolved in distilled water in a crucible of alumina, followed by stirring and mixing. The obtained aqueous solution was then heated to evaporate water for solidification. The solidified product was heated at 873 K in the atmosphere for 20 hours. The obtained calcinate was crushed and stirred, and then molded under pressure. The molded body was heated at 1123 K in a 300 ml/min oxygen stream for 20 hours. The product thus obtained was then crushed and stirred, and subsequently molded under pressure. The molded body was heated at 1273 K in a 300 ml/min oxygen stream for 20 hours. The product obtained was crushed and molded under pressure. The molded body was hot-press sintered at 1173 K in air under uniaxial pressure of 10 Mpa for 20 hours, thereby producing a complex oxide for n-type thermoelectric material.

The complex oxide for n-type thermoelectric material obtained was cut and formed into a rectangular parallelepiped which has a surface of 4 mm×4 mm in parallel to the pressing axis during hot pressing and a length of 5 mm perpendicular to the pressing axis, thereby producing an n-type thermoelectric material.

(3) Production of a Thermal Buffer Material for p-Type Thermoelectric Material

In the above-described production process of a complex oxide for p-type thermoelectric material, the oxide before hot-press sintering was crushed in a ball mill, thereby producing a complex oxide powder in which crystal grains with a longest dimension of 1 μm to 20 μm occupied 90% or more of the total number of crystal grains.

The obtained complex oxide powder was mixed with silver powder with the average particle diameter of about 45 μm in such a manner as to yield an oxide:silver ratio (weight ratio) of 5:5, and the mixture was sufficiently mixed using an agate mortar and pestle. To the mixture was admixed about 60 ml of an aqueous solution of 6.67 g/l of methyl cellulose hydroxide per total weight of 2 g of oxide powder and silver powder. In order to facilitate the dissolution of methyl cellulose hydroxide, 10 ml/l to 50 ml/l of ethanol and acetone were mixed per 1 liter of the solution.

Six ml of the obtained aqueous solution was poured into a plastic container with a size of 12 cm×8.5 cm and a depth of 1 cm, and was spread to have a uniform thickness. The solution was heated together with the container at 60° C. for 2 to 3 hours, to evaporate the solvent, thereby forming a film with a thickness of about 10 μm. Subsequently, another 6 ml of the same aqueous solution was poured on the film in the container, spread to have a uniform thickness, and dried in the same manner. This process was conducted four times in total, producing a film with a thickness of about 40 μm in which the silver powder and oxide powder were dispersed uniformly. The obtained film was cut into 5 mm squares, giving a film for forming a thermal buffer layer for p-type thermoelectric material.

(4) Production of a Thermal Buffer Material for n-Type Thermoelectric Conversion Materials

In the above-described production process of a complex oxide for n-type thermoelectric material, the oxide before hot-press sintering was crushed in a ball mill, thereby producing a complex oxide powder in which crystal grains with a longest dimension of 1 μm to 20 μm occupied 90% or more of the total number of crystal grains.

The production process of a thermal buffer material for p-type thermoelectric material was repeated except for using the oxide powder, thereby producing a film with a thickness of about 40 μm in which the silver powder and oxide powder were dispersed uniformly. The obtained film was cut into 5 mm squares, giving a film for forming a layer of a thermal buffer material for n-type thermoelectric material.

(5) Production of Thermoelectric Elements

Silver paste was applied to the surface of one side of an alumina substrate with a length of 10 mm, a thickness of 1 mm, a width of 5 mm, and was heated at 100° C. to evaporate the organic solvent over 1 hour. The alumina substrate coated with the silver paste was then heated at 800° C. for 15 minutes to form an electrically conductive thin-film of silver thereon, giving an electrically conductive substrate.

On the electrically conductive film of this electrically conductive substrate were placed one film for forming a thermal buffer layer for p-type thermoelectric material and one film for forming a thermal buffer layer for n-type thermoelectric material so that they might not overlap. On each of the respective films was further placed the p-type or the n-type thermoelectric material.

Subsequently, while applying a pressure of 0.1 t perpendicularly to the surface of the alumina substrate, a heat treatment was performed at 800° C. in air for 10 hours, giving a thermoelectric element. The obtained element was shaped as shown in FIG. 1 (I).

Heating and Rapid Cooling Test Results

The thermoelectric element obtained was heated at 1073 K (absolute temperature) for one hour in an electric furnace, and was taken out while hot, followed by rapid cooling. This operation was conducted 5 times in total to perform the heating and rapid cooling test.

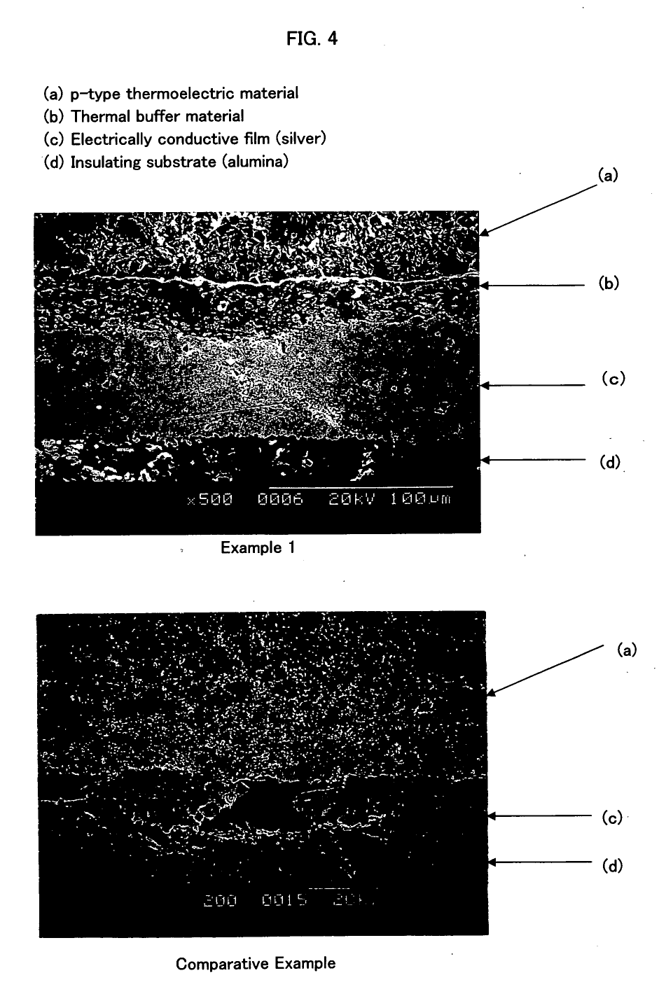

FIG. 4 shows a scanning electron micrograph of a section of the junction with the p-type thermoelectric material after the heating and rapid cooling test.

The above-described heating and rapid cooling test was conducted on a thermoelectric element prepared as a comparative example in the same manner as in Example 1 except using no thermal buffer materials. FIG. 4 also shows a scanning electron micrograph of a section of the junction with the p-type thermoelectric material of Comparative Example after the heating and rapid cooling test.

As can be seen from these micrographs, the thermoelectric element of Comparative Example had partially separated portions between the silver film and the thermoelectric material at the junction. In contrast, with regard to the thermoelectric element of Example 1 with the thermal buffer material provided at the junction, the silver film and the buffer material as well as the buffer material and the thermoelectric material were adhered to each other with no gap at the junctions therebetween, so that noticeable thermal-stress resistance was demonstrated. Such favorable adhesion was seen in all of Examples described later.

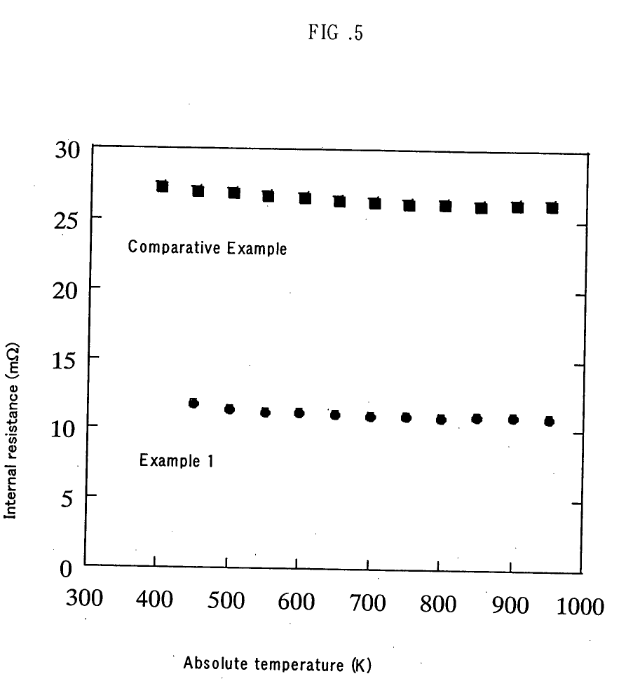

FIG. 5 is a graph showing the relation between the temperature and the internal resistance with regard to each of the thermoelectric elements of Example 1 and Comparative Example after being subjected to the heating and rapid cooling test. This graph shows that the internal resistance hardly increased in the element of Example 1 after the heating and rapid cooling test. The same result was seen in all of Examples described later.

These results show that thermoelectric elements of the invention have high thermal-stress durability at the junction of the thermoelectric material and the electrically conductive substrate, and can maintain favorable electrical properties for a long time of period. Accordingly, a thermoelectric module employing the thermoelectric elements of the invention can achieve a high electricity generating performance.

### Examples 2 to 5

Thermoelectric elements were produced in the same manner as in Example 1 except for using materials as in Table 1 as thermoelectric materials, thermal buffer materials, and electrically conductive films to be formed on an alumina substrate. The thermoelectric elements obtained were shaped as shown in FIG. 1 (I).

TABLE 1

| | Composition | Composition | | Mixing | | Mixing | Electrically | Net-like |
|---|---|---|---|---|---|---|---|---|
| | of a p-type | of an n-type | Composition of a thermal | Ratio | Composition of a thermal | Ratio | conductive | or fibrous |
| Ex. | thermoelectric material | thermoelectric material | buffer for p-type material | A:B | buffer for n-type material | A:B | film | material |
| 1 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | None |
| | | | B: Ag | | B: Ag | | | |
| 2 | Ca_{2.7}Bi_{0.3}Co₄O_{9.3} | LaNi_{0.9}Cu_{0.1}O_{2.9} | A: Ca_{2.7}Bi_{0.3}Co₄O_{9.3} | 5:5 | A: LaNi_{0.9}Cu_{0.1}O_{2.9} | 5:5 | Ag | None |
| | | | B: Ag | | B: Ag | | | |
| 3 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | None |
| | | | B: Au | | B: Au | | | |
| 4 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | None |
| | | | B: Ag | | B: Ag | | | |
| 5 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | None |
| | | | B: Pt | | B: Pt | | | |

### Example 6

A thermoelectric element was produced in the same manner as in Example 1 except for using a silver sheet with a length of 10 mm, a width of 5 mm, and a thickness of 100 μm as an electrically conductive substrate.

The thermoelectric element obtained was shaped as shown in FIG. 1 (II).

### Examples 7 to 9

Thermoelectric elements were produced in the same manner as in Example 6 except for using materials as in Table 2 as thermoelectric materials, thermal buffer materials, and electrically conductive substrates.

The thermoelectric elements obtained were shaped as shown in FIG. 1 (II).

TABLE 2

| | | | | | | | Electrically | |
|---|---|---|---|---|---|---|---|---|
| | Composition | Composition | | Mixing | | Mixing | conductive | Net-like or |
| | of a p-type | of an n-type | Composition of a thermal | Ratio | Composition of a thermal | Ratio | substrate | fibrous |
| Ex. | thermoelectric material | thermoelectric material | buffer for p-type material | A:B | buffer for n-type material | A:B | Thickness | material |
| 6 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | None |
| | | | B: Ag | | B: Ag | | 100 μm | |
| 7 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | None |
| | | | B: Au | | B: Au | | 500 μm | |
| 8 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | None |
| | | | B: Ag | | B: Ag | | 100 μm | |
| 9 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | None |
| | | | B: Pt | | B: Pt | | 100 μm | |

### Example 10

The same materials as in Example 1 were used as an electrically conductive substrate, thermoelectric materials, and thermal buffer materials, to produce a thermoelectric material provided with a thermal buffer material and a net-like or fibrous material at the junction of the thermoelectric material and the electrically conductive substrate in accordance with the following process.

Initially, on the electrically conductive film on an alumina substrate were placed one film for forming a thermal buffer layer for p-type thermoelectric material and one film for forming a thermal buffer layer for n-type thermoelectric material so that they might not overlap each other. A 40-mesh/inch silver net with a wire diameter of 100 μm was placed on each of the films, and p-type and n-type thermoelectric materials were separately placed on each of the silver nets.

Subsequently, while applying a pressure of 0.1 t perpendicularly to the surface of the alumina substrate, a heat treatment was performed at 800° C. in air for 10 hours, giving a thermoelectric element. The obtained element was shaped as shown in FIG. 2 (I).

### Examples 11 to 14

Materials as in Table 3 were used as thermoelectric materials, thermal buffer materials, and electrically conductive films to be formed on an alumina substrate.

Net-like or fibrous materials as in Table 3 were interposed between each thermoelectric material and the respective thermal buffer materials as in Example 10.

Thermoelectric elements were obtained in the same manner as in Example 10. The obtained elements were shaped as shown in FIG. 2 (I).

Note that the oxide whiskers used in Examples 11 and 13 were produced as follows.

Powders of Bi₂O₃, CaCO₃, SrCo₃ and CO₃O₄ were mixed in such a manner as to yield the atomic ratio of Bi:Ca:Sr:Co of 1:1:1:2 or 1:1:1:1. The mixture was heated in air at 1300° C. for 30 minutes using a crucible of alumina to produce a melt. The melt was rapidly cooled between two copper plates for solidification, giving a glass precursor. The glass precursor was placed on an alumina board, and the precursor obtained at the atomic ratio of 1:1:1:2 was heat-treated at 930° C. and the precursor obtained at the atomic ratio of 1:1:1:1 was treated at 900° C. in an oxygen stream for 100 hours. Whiskers growing from the precursor surface were collected using tweezers after cooling to room temperature, giving whiskers of the Bi₂Sr₂CO₂O₉ phase with the composition of Bi_{1.8-2.5}Sr_{1.1-2.5}Ca_{0-0.8}Co₂O_{8.5-10} from the precursor with the atomic ratio of 1:1:1:1 and whiskers of the Ca₃CO₄O₉ phase having the composition of Ca_{2.2-3.2}Sr_{0-0.2}Bi_{0.1-0.5}Co₄O_{8.5-10} from the precursor with the atomic ratio of 1:1:1:2. Five mg of each kind of whiskers thus obtained was used for the junctions with the p-type and n-type thermoelectric materials.

TABLE 3

| | | | | | | | Electri- | |
|---|---|---|---|---|---|---|---|---|
| | Composition | Composition | | | | | cally | |
| | of a p-type | of an n-type | Composition of a | Mixing | Composition of a | Mixing | conduc- | Net-like or fibrous |
| | thermoelectric | thermoelectric | thermal buffer | Ratio | thermal buffer for | Ratio | tive | material |
| Ex. | material | material | for p-type material | A:B | n-type material | A:B | film | Shape · Position |
| 10 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | | Wire diameter 100 μm |
| | | | | | | | | 40 mesh/inch |
| | | | | | | | | Between a thermoelectric |
| | | | | | | | | material and a buffer |
| | | | | | | | | material |
| 11 | Ca_{2.7}Bi_{0.3}Co₄O_{9.3} | La_{0.9}Ni_{0.9}Cu_{0.1}O_{2.9} | A: Ca_{2.7}Bi_{0.3}Co₄O_{9.3} | 5:5 | A: La_{0.9}Ni_{0.9}Cu_{0.1}O_{2.9} | 5:5 | Ag | Ca₃Co₄O₉ whisker |
| | | | B: Ag | | B: Ag | | | Length: 0.1-1.2 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 12 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | | Wire diameter 20 μm |
| | | | | | | | | 100 mesh/inch |
| | | | | | | | | Between a thermoelectric |
| | | | | | | | | material and a buffer |
| | | | | | | | | material |
| 13 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | | Length: 0.1-3 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 14 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | | Wire diameter 70 μm |
| | | | | | | | | 80 mesh/inch |
| | | | | | | | | Between a thermoelectric |
| | | | | | | | | material and a buffer |
| | | | | | | | | material |

### Example 15

A thermoelectric element was manufactured in the same manner as in Example 10 except for using a silver sheet with a length of 10 mm, a width of 5 mm, and a thickness of 100 μm as an electrically conductive substrate. The obtained element was shaped as shown in FIG. 2 (I), wherein the silver sheet was used as the electrically conductive substrate.

### Examples 16 to 19

Materials as in Table 4 were used as thermoelectric materials, thermal buffer materials, and electrically conductive substrates.

Net-like or fibrous materials as in Table 4 were interposed between each thermoelectric material and the respective thermal buffer materials as in Example 15.

Thermoelectric elements were obtained in the same manner as in Example 15. The obtained elements were shaped as shown in FIG. 2 (I), wherein the metal sheet was used as the electrically conductive substrate.

TABLE 4

| | | | | | | | Electri- | |
|---|---|---|---|---|---|---|---|---|
| | | | | | | | cally | |
| | | | | | | | conduc- | |
| | | | | | | | tive | |
| | Composition | Composition | Composition | | Composition | | sub- | |
| | of a p-type | of an n-type | of a | Mixing | of a thermal | Mixing | strate | |
| | thermoelectric | thermoelectric | thermal buffer | Ratio | buffer for n-type | Ratio | Thick- | Net-like or fibrous material |
| Ex. | material | material | for p-type material | A:B | material | A:B | ness | Shape · Position |
| 15 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | 100 μm | Wire diameter 100 μm |
| | | | | | | | | 40 mesh/inch |
| | | | | | | | | Between a thermoelectric |
| | | | | | | | | material and a buffer |
| | | | | | | | | material |
| 16 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Ca₃Co₄O₉ whisker |
| | | | B: Ag | | B: Ag | | 100 μm | Length: 0.1-1.2 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 17 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | 500 μm | Wire diameter 20 μm |
| | | | | | | | | 100 mesh/inch |
| | | | | | | | | Between a thermoelectric |
| | | | | | | | | material and a buffer |
| | | | | | | | | material |
| 18 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | 100 μm | Length: 0.1-3 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 19 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | 100 μm | Wire diameter 70 μm |
| | | | | | | | | 80 mesh/inch |
| | | | | | | | | Between a thermoelectric |
| | | | | | | | | material and a buffer |
| | | | | | | | | material |

### Example 20

A p-type thermoelectric material and an n-type thermoelectric material were produced in the same manner as in Example 1.

Films for forming thermal buffer layers for p-type and n-type thermoelectric materials were manufactured in the same manner as in Example 1 except that the thickness was 20 μm.

An alumina substrate with a thin film of silver produced in the same manner as in Example 1 was used as an electrically conductive substrate. On the electrically conductive substrate were placed one 20 μm-thick film for forming a thermal buffer layer for p-type thermoelectric material and one 20 μm-thick film for forming a thermal buffer layer for n-type thermoelectric material so that they might not overlap each other. A 40-mesh/inch silver net with a wire diameter of 100 μm in the form of 5 mm squares was placed on both of the films, and then a film for forming the thermal buffer layer and the thermoelectric material were placed thereon in that order.

Subsequently, while applying a pressure of 0.1 t perpendicularly to the surface of the alumina substrate, a heat treatment was performed at 800° C. in air for 10 hours, giving a thermoelectric element. The obtained element was shaped as shown in FIG. 2 (III).

### Examples 21 to 24

Materials as in Table 5 were used as thermoelectric materials, thermal buffer materials, and electrically conductive films to be formed on an alumina substrate.

Net-like or fibrous materials as in Table 5 were interposed between the thermal buffer films as in Example 20.

Thermoelectric elements were obtained in the same manner as in Example 20. The obtained elements were shaped as shown in FIG. 2 (III).

TABLE 5

| | | | | | | | Electri- | |
|---|---|---|---|---|---|---|---|---|
| | Composition | Composition | | | | | cally | |
| | of a p-type | of an n-type | Composition of a | Mixing | Composition of a | Mixing | conduc- | Net-like or fibrous |
| | thermoelectric | thermoelectric | thermal buffer | Ratio | thermal buffer for | Ratio | tive | material |
| Ex. | material | material | for p-type material | A:B | n-type material | A:B | film | Shape · Position |
| 20 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | | Wire diameter 100 μm |
| | | | | | | | | 40 mesh/inch |
| | | | | | | | | Interposed between |
| | | | | | | | | buffer films |
| 21 | Ca_{2.7}Bi_{0.3}Co₄O_{9.3} | La_{0.9}Ni_{0.9}Cu_{0.1}O_{2.9} | A: Ca_{2.7}Bi_{0.3}Co₄O_{9.3} | 5:5 | A: La_{0.9}Ni_{0.9}Cu_{0.1}O_{2.9} | 5:5 | Ag | Ca₃Co₄O₉ whisker |
| | | | B: Ag | | B: Ag | | | Length: 0.1-1.2 mm |
| | | | | | | | | Width: 10-100 μm |
| | | | | | | | | Thickness: 1-30 μm |
| | | | | | | | | Interposed between |
| | | | | | | | | buffer films |
| 22 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | | Wire diameter 20 μm |
| | | | | | | | | 100 mesh/inch |
| | | | | | | | | Interposed between |
| | | | | | | | | buffer films |
| 23 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | | Length: 0.1-3 mm |
| | | | | | | | | Width: 10-100 μm |
| | | | | | | | | Thickness: 1-30 μm |
| | | | | | | | | Interposed between |
| | | | | | | | | buffer films |
| 24 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | | Wire diameter 70 μm |
| | | | | | | | | 80 mesh/inch |
| | | | | | | | | Interposed between |
| | | | | | | | | buffer films |

### Example 25

A thermoelectric element was produced in the same manner as in Example 20 except for using a silver sheet with a length of 10 mm, a width of 5 mm, and a thickness of 100 μm as an electrically conductive substrate. The element obtained was shaped as shown in FIG. 2 (III), wherein the silver sheet was used as the electrically conductive substrate.

### Examples 26 to 29

Materials as in Table 6 were used as thermoelectric materials, thermal buffer materials, and electrically conductive substrates.

Net-like or fibrous materials as in Table 6 were interposed between the thermal buffer films as in Example 25.

Thermoelectric elements were obtained in the same manner as in Example 25. The obtained elements were shaped as shown in FIG. 2 (III), wherein the metal sheet was used as the electrically conductive substrate.

TABLE 6

| | | | | | | | Electri- | |
|---|---|---|---|---|---|---|---|---|
| | | | | | | | cally | |
| | | | | | | | conduc- | |
| | | | | | | | tive | |
| | Composition | Composition | Composition | | Composition | | sub- | |
| | of a p-type | of an n-type | of a | Mixing | of a thermal | Mixing | strate | |
| | thermoelectric | thermoelectric | thermal buffer | Ratio | buffer for n-type | Ratio | Thick- | Net-like or fibrous material |
| Ex. | material | material | for p-type material | A:B | material | A:B | ness | Shape · Position |
| 25 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | 100 μm | Wire diameter 100 μm |
| | | | | | | | | 40 mesh/inch |
| | | | | | | | | Interposed between |
| | | | | | | | | buffer films |
| 26 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Ca₃Co₄O₉ whisker |
| | | | B: Ag | | B: Ag | | 100 μm | Length: 0.1-1.2 mm |
| | | | | | | | | Width: 10-100 μm |
| | | | | | | | | Thickness: 1-30 μm |
| | | | | | | | | Interposed between |
| | | | | | | | | buffer films |
| 27 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | 500 μm | Wire diameter 20 μm |
| | | | | | | | | 100 mesh/inch |
| | | | | | | | | Interposed between |
| | | | | | | | | buffer films |
| 28 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | 100 μm | Length: 0.1-3 mm |
| | | | | | | | | Width: 10-100 μm |
| | | | | | | | | Thickness: 1-30 μm |
| | | | | | | | | Interposed between |
| | | | | | | | | buffer films |
| 29 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | 100 μm | Wire diameter 70 μm |
| | | | | | | | | 80 mesh/inch |
| | | | | | | | | Interposed between |
| | | | | | | | | buffer films |

### Example 30

A thermoelectric element was produced in the same manner as in Example 10 using the materials of Example 10 as thermoelectric materials, thermal buffer materials, an electrically conductive substrate, and a net-like material except that the net-like material was interposed between each thermal buffer material and the electrically conductive film of the electrically conductive substrate. The obtained thermoelectric element was shaped as shown in FIG. 2 (II).

### Examples 31 to 34

Materials as in Table 7 were used as thermoelectric materials, thermal buffer materials, and electrically conductive films to be formed on an alumina substrate.

Net-like or fibrous materials as in Table 7 were interposed between each thermoelectric material and the electrically conductive film of the electrically conductive substrate in the same manner as in Example 30.

Thermoelectric elements were obtained in the same manner as in Example 30. The obtained elements were shaped as shown in FIG. 2 (II).

TABLE 7

| | | | | | | | Electri- | |
|---|---|---|---|---|---|---|---|---|
| | Composition | Composition | | | | | cally | |
| | of a p-type | of an n-type | Composition of a | Mixing | Composition of a | Mixing | conduc- | Net-like or fibrous |
| | thermoelectric | thermoelectric | thermal buffer | Ratio | thermal buffer for | Ratio | tive | material |
| Ex. | material | material | for p-type material | A:B | n-type material | A:B | film | Shape · Position |
| 30 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | | Wire diameter 100 μm |
| | | | | | | | | 40 mesh/inch |
| | | | | | | | | Between a buffer |
| | | | | | | | | material and an |
| | | | | | | | | electrically |
| | | | | | | | | conductive film |
| 31 | Ca_{2.7}Bi_{0.3}Co₄O_{9.3} | La_{0.9}Ni_{0.9}Cu_{0.1}O_{2.9} | A: Ca_{2.7}Bi_{0.3}Co₄O_{9.3} | 5:5 | A: La_{0.9}Ni_{0.9}Cu_{0.1}O_{2.9} | 5:5 | Ag | Ca₃Co₄O₉ whisker |
| | | | B: Ag | | B: Ag | | | Length: 0.1-1.2 mm |
| | | | | | | | | Width: 10-100 μm |
| | | | | | | | | Thickness: 1-30 μm |
| | | | | | | | | Between a buffer |
| | | | | | | | | material and an |
| | | | | | | | | electrically |
| | | | | | | | | conductive film |
| 32 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | | Wire diameter 20 μm |
| | | | | | | | | 100 mesh/inch |
| | | | | | | | | Between a buffer |
| | | | | | | | | material and an |
| | | | | | | | | electrically |
| | | | | | | | | conductive film |
| 33 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | | Length: 0.1-3 mm |
| | | | | | | | | Width: 10-100 μm |
| | | | | | | | | Thickness: 1-30 μm |
| | | | | | | | | Between a buffer |
| | | | | | | | | material and an |
| | | | | | | | | electrically |
| | | | | | | | | conductive film |
| 34 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | | Wire diameter 70 μm |
| | | | | | | | | 80 mesh/inch |
| | | | | | | | | Between a buffer |
| | | | | | | | | material and an |
| | | | | | | | | electrically |
| | | | | | | | | conductive film |

### Example 35

A thermoelectric element was produced in the same manner as in Example 30 except for using a silver sheet with a length of 10 mm, a width of 5 mm, and a thickness of 100 μm as the electrically conductive substrate. The element obtained was shaped as shown in FIG. 2 (II), wherein the silver sheet was used as the electrically conductive substrate.

### Examples 36 to 39

Materials as in Table 8 were used as thermoelectric materials, thermal buffer materials, and electrically conductive substrates.

Net-like or fibrous materials as in Table 8 were interposed between each thermoelectric material and the electrically conductive substrate as in Example 35.

Thermoelectric elements were obtained in the same manner as in Example 35. The obtained elements were shaped as shown in FIG. 2 (II), wherein the metal sheet was used as the electrically conductive substrate.

TABLE 8

| | | | | | | | Electri- | |
|---|---|---|---|---|---|---|---|---|
| | | | | | | | cally | |
| | | | | | | | conduc- | |
| | | | | | | | tive | |
| | Composition | Composition | Composition | | Composition | | sub- | |
| | of a p-type | of an n-type | of a | Mixing | of a thermal | Mixing | strate | |
| | thermoelectric | thermoelectric | thermal buffer | Ratio | buffer for n-type | Ratio | Thick- | Net-like or fibrous material |
| Ex. | material | material | for p-type material | A:B | material | A:B | ness | Shape · Position |
| 35 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Silver net, |
| | | | B: Ag | | B: Ag | | 100 μm | Wire diameter 100 μm |
| | | | | | | | | 40 mesh/inch |
| | | | | | | | | Between a buffer |
| | | | | | | | | material and an |
| | | | | | | | | electrically |
| | | | | | | | | conductive substrate |
| 36 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | Ca₃Co₄O₉ whisker |
| | | | B: Ag | | B: Ag | | 100 μm | Length: 0.1-1.2 mm |
| | | | | | | | | Width: 10-100 μm |
| | | | | | | | | Thickness: 1-30 μm |
| | | | | | | | | Between a buffer |
| | | | | | | | | material and an |
| | | | | | | | | electrically |
| | | | | | | | | conductive substrate |
| 37 | Ca₃Co₄O₉ | La₂Ni_{0.9}Cu_{0.1}O_{3.9} | A: Ca₃Co₄O₉ | 5:5 | A: La₂Ni_{0.9}Cu_{0.1}O_{3.9} | 5:5 | Au | Gold net, |
| | | | B: Au | | B: Au | | 500 μm | Wire diameter 20 μm |
| | | | | | | | | 100 mesh/inch |
| | | | | | | | | Between a buffer |
| | | | | | | | | material and an |
| | | | | | | | | electrically |
| | | | | | | | | conductive substrate |
| 38 | Bi₂Sr₂Co₂O_{9.3} | La_{0.9}Bi_{0.1}NiO_{3.0} | A: Bi₂Sr₂Co₂O_{9.3} | 6:4 | A: La_{0.9}Bi_{0.1}NiO_{3.0} | 5:5 | Ag | Bi₂Sr₂Co₂O₉ whisker |
| | | | B: Ag | | B: Ag | | 100 μm | Length: 0.1-3 mm |
| | | | | | | | | Width: 10-100 μm |
| | | | | | | | | Thickness: 1-30 μm |
| | | | | | | | | Between a buffer |
| | | | | | | | | material and an |
| | | | | | | | | electrically |
| | | | | | | | | conductive substrate |
| 39 | Bi_{1.8}Pb_{0.2}Sr₂Co₂O_{9.1} | LaNi_{0.9}Cu_{0.1}O_{2.8} | A: Bi₂Sr₂Co₂O_{9.3} | 6:4 | A: LaNi_{0.9}Cu_{0.1}O_{2.8} | 4:6 | Pt | Platinum net |
| | | | B: Pt | | B: Pt | | 100 μm | Wire diameter 70 μm |
| | | | | | | | | 80 mesh/inch |
| | | | | | | | | Between a buffer |
| | | | | | | | | material and an |
| | | | | | | | | electrically |
| | | | | | | | | conductive substrate |

### Example 40

In the same manner as in the production process of the thermal buffer layer for p-type thermoelectric material of Example 1, four aqueous solutions were produced by mixing oxide powder and silver powder in the oxide:silver ratios (weight ratio) of 8:2, 6:4, 4:6, and 2:8.

Using these aqueous solutions, 6 ml of the aqueous solution with the oxide:silver ratio of 8:2 was first poured in a plastic container with a size of 12 cm×8.5 cm and a depth of 1 cm, and spread to have a uniform thickness. The solution was heated together with the container at 60° C. for 2 to 3 hours, to evaporate the solvent, thereby forming a film with a thickness of about 10 μm. Subsequently, 6 ml of the aqueous solution with the oxide:silver ratio of 6:4 was poured on the film formed in the container, and spread to have a uniform thickness, followed by drying in the same manner. The aqueous solutions with the oxide:silver ratios of 4:6 and 2:8 were further deposited thereon in the same manner, thereby producing a film with a total thickness of about 40 μm for forming a thermal buffer layer for p-type thermoelectric material.

Separately, in the same manner as in the production process of the film for forming a thermal buffer layer for n-type thermoelectric material of Example 1, four aqueous solutions were produced by mixing oxide powder and silver powder in the oxide:silver ratios (weight ratio) of 8:2, 6:4, 4:6, and 2:8. Subsequently, in the same manner as described above, a film with the total thickness of about 40 μm for forming a thermal buffer layer for n-type thermoelectric material was produced wherein the oxide:silver ratio varied within the range of 8:2 to 2:8 in steps of 10 μm.

A thermoelectric material was produced in the same manner as in Example 1 except for using the films for forming thermal buffer layers thus obtained. Note that the films for forming the thermal buffer layers were disposed in such a manner that the side with a high oxide content was in contact with the thermoelectric material. The thermoelectric element thus obtained was shaped as shown in FIG. 1 (I), wherein thermal buffer layers with graded compositions were formed.

### Examples 41 to 44

Thermoelectric elements were manufactured in the same manner as in Example 40 except for using the materials as in Table 9 as thermoelectric materials, thermal buffer materials, and electrically conductive films to be formed on an alumina substrate. The thermoelectric elements thus obtained were shaped as shown in FIG. 1 (I), wherein thermal buffer layers with graded compositions were formed.

Note that the thermal buffer layers were produced using a film with a total thickness of 40 μm wherein the oxide:metal mixing ratios varied as shown in Table 9.

TABLE 9

| | | Composition | | | | | | |
|---|---|---|---|---|---|---|---|---|
| | Composition of | of an n-type | Composition of a | Mixing | Composition of a | Mixing | Electrically | Net-like or fibrous |
| | a p-type | thermoelectric | thermal buffer for | Ratio | thermal buffer for | Ratio | conductive | material |
| Ex. | thermoelectric material | material | p-type material | A:B | n-type material | A:B | film | Shape · Position |
| 40 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | None |
| | | | B: Ag | 4:6 | B: Ag | 4:6 | | |
| | | | | 6:4 | | 6:4 | | |
| | | | | 8:2 | | 8:2 | | |
| 41 | Ca_{2.7}Bi_{0.3}Co₄O_{9.3} | LaNi_{0.9}Cu_{0.1}O_{2.9} | A: Ca_{2.7}Bi_{0.3}Co₄O_{9.3} | 2:8 | A: LaNi_{0.9}Cu_{0.1}O_{2.9} | 2:8 | Ag | None |
| | | | B: Ag | 4:6 | B: Ag | 4:6 | | |
| | | | | 6:4 | | 6:4 | | |
| | | | | 8:2 | | 8:2 | | |
| 42 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | None |
| | | | B: Au | 8:2 | B: Au | 8:2 | | |
| 43 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | None |
| | | | B: Ag | 6:4 | B: Ag | 6:4 | | |
| 44 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | None |
| | | | B: Pt | 4:6 | B: Pt | 4:6 | | |
| | | | | 6:4 | | 6:4 | | |
| | | | | 8:2 | | 8:2 | | |

### Example 45

A thermoelectric element was produced in the same manner as in Example 40 except for using a silver sheet with a length of 10 mm, a width of 5 mm, and a thickness of 100 μm as an electrically conductive substrate.

The thermoelectric element thus obtained was shaped as shown in FIG. 1 (II), wherein thermal buffer layers with graded compositions were formed.

### Examples 46 to 48

Thermoelectric elements were manufactured in the same manner as in Example 45 except for using the materials as in Table 10 as thermoelectric materials, thermal buffer materials, and electrically conductive substrates.

The thermoelectric elements thus obtained were shaped as shown in FIG. 1 (II), wherein thermal buffer layers with graded compositions were formed.

TABLE 10

| | | Composition | | | | | Electrically | |
|---|---|---|---|---|---|---|---|---|
| | Composition | of an n-type | Composition of a | Mixing | Composition of a | Mixing | conductive | Net-like or fibrous |
| | of a p-type | thermoelectric | thermal buffer for | Ratio | thermal buffer for | Ratio | substrate | material |
| Ex. | thermoelectric material | material | p-type material | A:B | n-type material | A:B | Thickness | Shape · Position |
| 45 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | None |
| | | | B: Ag | 4:6 | B: Ag | 4:6 | 100 μm | |
| | | | | 6:4 | | 6:4 | | |
| | | | | 8:2 | | 8:2 | | |
| 46 | Ca₃Co₄O₉ | La₂Ni_{0.9}Cu_{0.1}O_{2.9} | A: Ca₃Co₄O₉ | 2:8 | A: La₂Ni_{0.9}Cu_{0.1}O_{3.9} | 2:8 | Au | None |
| | | | B: Au | 8:2 | B: Au | 8:2 | 500 μm | |
| 47 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | None |
| | | | B: Ag | 6:4 | B: Ag | 6:4 | 100 μm | |
| 48 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | None |
| | | | B: Pt | 4:6 | B: Pt | 4:6 | 100 μm | |
| | | | | 6:4 | | 6:4 | | |
| | | | | 8:2 | | 8:2 | | |

### Example 49

Using the same materials as in Example 40 as an electrically conductive substrate, thermoelectric materials, and thermal buffer materials, a thermoelectric element was manufactured in accordance with the following process, wherein a thermal buffer material and a net-like material were provided at the junctions of the thermoelectric materials with the electrically conductive substrate.

Initially, on the electrically conductive film of an alumina substrate were placed one film for forming a thermal buffer layer for p-type thermoelectric material and one film for forming a thermal buffer layer for n-type thermoelectric material so that they might not overlap each other. A 40-mesh/inch silver net with a wire diameter of 100 μm was placed on each of the films, and p-type and n-type thermoelectric materials were separately placed on each of the silver nets.

Subsequently, while applying a pressure of 0.1 t perpendicularly to the surface of the alumina substrate, a heat treatment was performed at 800° C. in air for 10 hours, giving a thermoelectric element. The thermoelectric element obtained was shaped as shown in FIG. 2 (I), wherein thermal buffer layers with graded compositions were formed.

### Examples 50 to 53

Materials as in Table 11 were used as thermoelectric materials, thermal buffer materials, and electrically conductive films to be formed on an alumina substrate.

Net-like or fibrous materials as in Table 11 were interposed between each thermoelectric material and the respective thermal buffer materials as in Example 49.

Thermoelectric elements were obtained in the same manner as in Example 49. The obtained thermoelectric elements were shaped as shown in FIG. 2 (I), wherein thermal buffer layers with graded compositions were formed.

TABLE 11

| | Composition of | Composition of | | | | | Electri- | |
|---|---|---|---|---|---|---|---|---|
| | a p-type | an n-type | Composition of | Mixing | Composition of | Mixing | cally | Net-like |
| | thermoelectric | thermoelectric | a thermal buffer | Ratio | a thermal buffer | Ratio | conductive | or fibrous material |
| Ex. | material | material | for p-type material | A:B | for n-type material | A:B | film | Shape · Position |
| 49 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | | Wire diameter 100 μm |
| | | | | 6:4 | | 6:4 | | 40 mesh/inch |
| | | | | 8:2 | | 8:2 | | Between a thermoelectric |
| | | | | | | | | material and a buffer |
| | | | | | | | | material |
| 50 | Ca_{2.7}Bi_{0.3}Co₄O_{9.3} | LaNi_{0.9}Cu_{0.1}O_{2.9} | A: Ca_{2.7}Bi_{0.3}Co₄O_{9.3} | 2:8 | A: LaNi_{0.9}Cu_{0.1}O_{2.9} | 2:8 | Ag | Ca₃Co₄O₉ whisker |
| | | | B: Ag | 4:6 | B: Ag | 4:6 | | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Between a thermoelectric |
| | | | | | | | | material and a buffer |
| | | | | | | | | material |
| 51 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | | Wire diameter 20 μm |
| | | | | | | | | 100 mesh/inch |
| | | | | | | | | Between a thermoelectric |
| | | | | | | | | material and a buffer |
| | | | | | | | | material |
| 52 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | | Length: 0.1-3 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 53 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Platinum net |
| | | | B: Pt | 4:6 | B: Pt | 4:6 | | Wire diameter 70 μm |
| | | | | 6:4 | | 6:4 | | 80 mesh/inch |
| | | | | 8:2 | | 8:2 | | Between a thermoelectric |
| | | | | | | | | material and a buffer |
| | | | | | | | | material |

### Example 54

A thermoelectric element was produced in the same manner as in Example 49 except for using a silver sheet with a length of 10 mm, a width of 5 mm, and a thickness of 100 μm as an electrically conductive substrate. The element obtained was shaped as shown in FIG. 2 (I), wherein the silver sheet was used as the electrically conductive substrate and thermal buffer layers with graded compositions were formed.

### Examples 55 to 58

Materials as in Table 12 were used as thermoelectric materials, thermal buffer materials, and electrically conductive substrates.

Net-like or fibrous materials as in Table 12 were interposed between each thermoelectric material and the respective thermal buffer materials as in Example 54.

Thermoelectric elements were obtained in the same manner as in Example 54. The obtained thermoelectric elements were shaped as shown in FIG. 2 (I), wherein the metal sheet was used as the electrically conductive substrate and thermal buffer layers with graded compositions were formed.

TABLE 12

| | | | | | | | Electri- | |
|---|---|---|---|---|---|---|---|---|
| | Composition of | Composition of | | | | | cally | |
| | a p-type | an n-type | Composition of | Mixing | Composition of | Mixing | conductive | Net-like |
| | thermoelectric | thermoelectric | a thermal buffer | Ratio | a thermal buffer | Ratio | substrate | or fibrous material |
| Ex. | material | material | for p-type material | A:B | for n-type material | A:B | Thickness | Shape · Position |
| 54 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | 100 μm | Wire diameter 100 μm |
| | | | | 6:4 | | 6:4 | | 40 mesh/inch |
| | | | | 8:2 | | 8:2 | | Between a thermoelectric |
| | | | | | | | | material and a buffer |
| | | | | | | | | material |
| 55 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Ca₃Co₄O₉ whisker |
| | | | B: Ag | 4:6 | B: Ag | 4:6 | 100 μm | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Between a thermoelectric |
| | | | | | | | | material and a buffer |
| | | | | | | | | material |
| 56 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | 500 μm | Wire diameter 20 μm |
| | | | | | | | | 100 mesh/inch |
| | | | | | | | | Between a thermoelectric |
| | | | | | | | | material and a buffer |
| | | | | | | | | material |
| 57 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | 100 μm | Length: 0.1-3 mm |
| | | | | | | | | Width: 10-100 μm |
| | | | | | | | | Thickness: 1-30 μm |
| | | | | | | | | Between a thermoelectric |
| | | | | | | | | material and a buffer |
| | | | | | | | | material |
| 58 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Platinum net |
| | | | B: Pt | 4:6 | B: Pt | 4:6 | 100 μm | Wire diameter 70 μm |
| | | | | 6:4 | | 6:4 | | 80 mesh/inch |
| | | | | 8:2 | | 8:2 | | Between a thermoelectric |
| | | | | | | | | material and a buffer |
| | | | | | | | | material |

### Example 59

In the same manner as in Example 40, four aqueous solutions were produced by mixing oxide powder and silver powder in the oxide:silver ratios (weight ratio) of 8:2, 6:4, 4:6, and 2:8.

Using these aqueous solutions, 6 ml of the aqueous solution with the oxide:silver ratio of 8:2 was first poured in a plastic container with a size of 12 cm×8.5 cm and a depth of 1 cm, and spread to have a uniform thickness. The solution was heated together with the container at 60° C. for 2 to 3 hours, to evaporate the solvent, thereby forming a film with a thickness of about 10 μm. Subsequently, 6 ml of the aqueous solution with the oxide:silver ratio of 6:4 was poured on the film formed in the container, spread to have a uniform thickness, and dried in the same manner, giving a double-layered film. Thus, the double-layered film with a thickness of about 20 μm for forming a thermal buffer layer for p-type thermoelectric material was produced.

Moreover, in the same manner as described above, the aqueous solutions with the oxide:silver ratio of 4:6 and 2:8 were used to produce another double-layered film with a thickness of about 20 μm for forming a thermal buffer layer for p-type thermoelectric material.

Separately, as films for forming thermal buffer layer for n-type thermoelectric material, the two aqueous solutions with the oxide:silver ratios of 8:2 and 6:4 and the two aqueous solutions with the oxide:silver ratios of 4:6 and 2:8 were used to produce two different types of double-layered films with thicknesses of about 20 μm in the same manner as described above.

In the same manner as in Example 1, an alumina substrate on which a thin film of silver was formed was used as an electrically conductive substrate. One of the 20-μm thick films for forming a thermal buffer layer for p-type thermoelectric material and one of the 20-μm thick films for forming a thermal buffer layer for n-type thermoelectric material were placed on the conductive substrate without overlapping each other in such a manner as that the side with a high silver content was in contact with the thin film of silver. Each film was a double-layered film wherein the mixing ratios (weight ratio) of oxide to silver were 4:6 and 2:8. Subsequently, a 40-mesh/inch silver net with a wire diameter of 100 μm was placed on each of the films. On each of the silver nets was further placed the other 20-μm thick film for forming a thermal buffer layer for p-type thermoelectric material and the other 20-μm thick film for forming a thermal buffer layer for n-type thermoelectric material. Each film was a double-layered film wherein the mixing ratios (weight ratio) of oxide to silver were 8:2 and 6:4. These were disposed in such a manner as that the side with a high oxide content was in contact with the thermoelectric material.

Thereafter, thermoelectric materials were placed on each of the thermal buffer layers. While applying a pressure of 0.1 t perpendicularly to the surface of the alumina substrate, a heat treatment was performed at 800° C. in air for 10 hours, giving a thermoelectric element. The element thus obtained was shaped as shown in FIG. 2 (III), wherein thermal buffer layers with graded compositions were formed.

### Examples 60 to 63

Thermoelectric elements were manufactured in the same manner as in Example 59 except for using materials as in Table 13 as thermoelectric materials, thermal buffer materials, and electrically conductive films to be formed on an alumina substrate. The thermoelectric elements thus obtained were shaped as shown in FIG. 2 (III), wherein thermal buffer layers with graded compositions were formed.

Each thermal buffer layer was produced using two films with a thickness of 20 μm wherein the mixing ratios of oxide to metal varied as shown in Table 13.

TABLE 13

| | Composition of | Composition of | | | | | | |
|---|---|---|---|---|---|---|---|---|
| | a p-type | an n-type | Composition of | Mixing | Composition of | Mixing | | Net-like |
| | thermoelectric | thermoelectric | a thermal buffer | Ratio | a thermal buffer | Ratio | conductive | or fibrous material |
| Ex. | material | material | for p-type material | A:B | for n-type material | A:B | film | Shape · Position |
| 59 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | | Wire diameter 100 μm |
| | | | | 6:4 | | 6:4 | | 40 mesh/inch |
| | | | | 8:2 | | 8:2 | | Interposed between |
| | | | | | | | | buffer films |
| 60 | Ca_{2.7}Bi_{0.3}Co₄O_{9.3} | LaNi_{0.9}Cu_{0.1}O_{2.9} | A: Ca_{2.7}Bi_{0.3}Co₄O_{9.3} | 2:8 | A: LaNi_{0.9}Cu_{0.1}O_{2.9} | 2:8 | Ag | Ca₃Co₄O₉ whisker |
| | | | B: Ag | 4:6 | B: Ag | 4:6 | | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Interposed between |
| | | | | | | | | buffer films |
| 61 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | | Wire diameter 20 μm |
| | | | | | | | | 100 mesh/inch |
| | | | | | | | | Interposed between |
| | | | | | | | | buffer films |
| 62 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | | Length: 0.1-3 mm |
| | | | | | | | | Width: 10-100 μm |
| | | | | | | | | Thickness: 1-30 μm |
| | | | | | | | | Interposed between |
| | | | | | | | | buffer films |
| 63 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Platinum net |
| | | | B: Pt | 4:6 | B: Pt | 4:6 | | Wire diameter 70 μm |
| | | | | 6:4 | | 6:4 | | 80 mesh/inch |
| | | | | 8:2 | | 8:2 | | Interposed between |
| | | | | | | | | buffer films |

### Example 64

A thermoelectric element was produced in the same manner as in Example 59 except for using a silver sheet with a length of 10 mm, a width of 5 mm, and a thickness of 100 μm as an electrically conductive substrate. The element obtained was shaped as shown in FIG. 2 (III), wherein the silver sheet was used as a conductive substrate and thermal buffer layers with graded compositions were formed.

### Examples 65 to 68

Materials as in Table 14 were used as thermoelectric materials, thermal buffer materials, and electrically conductive substrates.

Net-like or fibrous materials as in Table 14 were interposed between the thermal buffer films as in Example 64.

Thermoelectric elements were obtained in the same manner as in Example 64. The obtained thermoelectric elements were shaped as shown in FIG. 2 (III), wherein a metal sheet was used as the electrically conductive substrate and thermal buffer layers with graded compositions were formed.

TABLE 14

| | Composition of | Composition of | | | | | Electrically | |
|---|---|---|---|---|---|---|---|---|
| | a p-type | an n-type | Composition of | Mixing | Composition of | Mixing | conductive | Net-like |
| | thermoelectric | thermoelectric | a thermal buffer | Ratio | a thermal buffer | Ratio | substrate | or fibrous material |
| Ex. | material | material | for p-type material | A:B | for n-type material | A:B | Thickness | Shape · Position |
| 64 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | 100 μm | Wire diameter 100 μm |
| | | | | 6:4 | | 6:4 | | 40 mesh/inch |
| | | | | 8:2 | | 8:2 | | Interposed between |
| | | | | | | | | buffer films |
| 65 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Ca₃Co₄O₉ whisker |
| | | | B: Ag | 4:6 | B: Ag | 4:6 | 100 μm | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Interposed between |
| | | | | | | | | buffer films |
| 66 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | 500 μm | Wire diameter 20 μm |
| | | | | | | | | 100 mesh/inch |
| | | | | | | | | Interposed between |
| | | | | | | | | buffer films |
| 67 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | 100 μm | Length: 0.1-3 mm |
| | | | | | | | | Width: 10-100 μm |
| | | | | | | | | Thickness: 1-30 μm |
| | | | | | | | | Interposed between |
| | | | | | | | | buffer films |
| 68 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Platinum net |
| | | | B: Pt | 4:6 | B: Pt | 4:6 | 100 μm | Wire diameter 70 μm |
| | | | | 6:4 | | 6:4 | | 80 mesh/inch |
| | | | | 8:2 | | 8:2 | | Interposed between |
| | | | | | | | | buffer films |

### Example 69

The same materials as in Example 49 were used as the electrically conductive film to be formed on an alumina substrate, thermoelectric materials, thermal buffer materials, and net-like or fibrous materials. A thermoelectric element was obtained in the same manner as in Example 49 except that the net-like or fibrous materials were interposed between each thermal buffer layer and the electrically conductive film of the electrically conductive substrate.

The obtained thermoelectric element was shaped as shown in FIG. 2 (II), wherein thermal buffer layers with graded compositions were formed.

### Examples 70 to 73

Materials as in Table 15 were used as thermoelectric materials, thermal buffer materials, and electrically conductive films to be formed on an alumina substrate.

Net-like or fibrous materials as in Table 15 were interposed between each thermal buffer layer and the electrically conductive film on the electrically conductive substrate as in Example 69.

Thermoelectric elements were obtained in the same manner as in Example 69. The obtained thermoelectric elements were shaped as shown in FIG. 2 (II), wherein a metal film was used as an electrically conductive film and thermal buffer layers with graded compositions were formed.

TABLE 15

| | Composition of | Composition of | | | | | Electri- | |
|---|---|---|---|---|---|---|---|---|
| | a p-type | an n-type | Composition of | Mixing | Composition of | Mixing | cally | Net-like |
| | thermoelectric | thermoelectric | a thermal buffer | Ratio | a thermal buffer | Ratio | conductive | or fibrous material |
| Ex. | material | material | for p-type material | A:B | for n-type material | A:B | film | Shape · Position |
| 69 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | | Wire diameter 100 μm |
| | | | | 6:4 | | 6:4 | | 40 mesh/inch |
| | | | | 8:2 | | 8:2 | | Between an electrically |
| | | | | | | | | conductive film |
| | | | | | | | | and a buffer material |
| 70 | Ca_{2.7}Bi_{0.3}Co₄O_{9.3} | LaNi_{0.9}Cu_{0.1}O_{2.9} | A: Ca_{2.7}Bi_{0.3}Co₄O_{9.3} | 2:8 | A: LaNi_{0.9}Cu_{0.1}O_{2.9} | 2:8 | Ag | Ca₃Co₄O₉ whisker |
| | | | B: Ag | 4:6 | B: Ag | 4:6 | | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Between an electrically |
| | | | | | | | | conductive film |
| | | | | | | | | and a buffer material |
| 71 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | | Wire diameter 20 μm |
| | | | | | | | | 100 mesh/inch |
| | | | | | | | | Between an electrically |
| | | | | | | | | conductive film |
| | | | | | | | | and a buffer material |
| 72 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | | Length: 0.1-3 mm |
| | | | | | | | | Width: 10-100 μm |
| | | | | | | | | Thickness: 1-30 μm |
| | | | | | | | | Between an electrically |
| | | | | | | | | conductive film |
| | | | | | | | | and a buffer material |
| 73 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Platinum net |
| | | | B: Pt | 4:6 | B: Pt | 4:6 | | Wire diameter 70 μm |
| | | | | 6:4 | | 6:4 | | 80 mesh/inch |
| | | | | 8:2 | | 8:2 | | Between an electrically |
| | | | | | | | | conductive film |
| | | | | | | | | and a buffer material |

### Example 74

A thermoelectric element was produced in the same manner as in Example 69 except for using a silver sheet with a length of 10 mm, a width of 5 mm, and a thickness of 100 μm as an electrically conductive substrate. The element obtained was shaped as shown in FIG. 2 (II), wherein the silver sheet was used as an electrically conductive substrate and thermal buffer layers with graded compositions were formed.

### Examples 75 to 78

Materials as in Table 16 were used as thermoelectric materials, thermal buffer materials, and electrically conductive substrates.

Net-like or fibrous materials as in Table 16 were interposed between each thermal buffer layer and the electrically conductive substrate as in Example 74.

Thermoelectric elements were obtained in the same manner as in Example 74 except that the above conditions were satisfied. The obtained thermoelectric elements were shaped as shown in FIG. 2 (II), wherein a metal sheet was used as an electrically conductive substrate and thermal buffer layers with graded compositions were formed.

TABLE 16

| | | | | | | | Electri- | |
|---|---|---|---|---|---|---|---|---|
| | Composition of | Composition of | | | | | cally | |
| | a p-type | an n-type | Composition of | Mixing | Composition of | Mixing | conductive | Net-like |
| | thermoelectric | thermoelectric | a thermal buffer | Ratio | a thermal buffer | Ratio | substrate | or fibrous material |
| Ex. | material | material | for p-type material | A:B | for n-type material | A:B | Thickness | Shape · Position |
| 74 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Silver net, |
| | | | B: Ag | 4:6 | B: Ag | 4:6 | 100 μm | Wire diameter 100 μm |
| | | | | 6:4 | | 6:4 | | 40 mesh/inch |
| | | | | 8:2 | | 8:2 | | Between an electrically |
| | | | | | | | | conductive substrate |
| | | | | | | | | and a buffer material |
| 75 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 2:8 | A: La_{0.9}Bi_{0.1}NiO_{3.0} | 2:8 | Ag | Ca₃Co₄O₉ whisker |
| | | | B: Ag | 4:6 | B: Ag | 4:6 | 100 μm | Length: 0.1-1.2 mm |
| | | | | 6:4 | | 6:4 | | Width: 10-100 μm |
| | | | | 8:2 | | 8:2 | | Thickness: 1-30 μm |
| | | | | | | | | Between an electrically |
| | | | | | | | | conductive substrate |
| | | | | | | | | and a buffer material |
| 76 | Ca₃Co₄O₉ | La₂Ni_{0.9}Cu_{0.1}O_{3.9} | A: Ca₃Co₄O₉ | 2:8 | A: La₂Ni_{0.9}Cu_{0.1}O_{3.9} | 2:8 | Au | Gold net, |
| | | | B: Au | 8:2 | B: Au | 8:2 | 500 μm | Wire diameter 20 μm |
| | | | | | | | | 100 mesh/inch |
| | | | | | | | | Between an electrically |
| | | | | | | | | conductive substrate |
| | | | | | | | | and a buffer material |
| 77 | Bi₂Sr₂Co₂O_{9.3} | La_{0.9}Bi_{0.1}NiO_{3.0} | A: Bi₂Sr₂Co₂O_{9.3} | 4:6 | A: La_{0.9}Bi_{0.1}NiO_{3.0} | 4:6 | Ag | Bi₂Sr₂Co₂O₉ whisker |
| | | | B: Ag | 6:4 | B: Ag | 6:4 | 100 μm | Length: 0.1-3 mm |
| | | | | | | | | Width: 10-100 μm |
| | | | | | | | | Thickness: 1-30 μm |
| | | | | | | | | Between an electrically |
| | | | | | | | | conductive substrate |
| | | | | | | | | and a buffer material |
| 78 | Bi_{1.8}Pb_{0.2}Sr₂Co₂O_{9.1} | LaNi_{0.9}Cu_{0.1}O_{2.8} | A: Bi₂Sr₂Co₂O_{9.3} | 2:8 | A: LaNi_{0.9}Cu_{0.1}O_{2.8} | 2:8 | Pt | Gold net |
| | | | B: Pt | 4:6 | B: Pt | 4:6 | 100 μm | Wire diameter 20 μm |
| | | | | 6:4 | | 6:4 | | 100 mesh/inch |
| | | | | 8:2 | | 8:2 | | Between an electrically |
| | | | | | | | | conductive substrate |
| | | | | | | | | and a buffer material |

### Example 79

Silver paste was applied to the surface of one side of an alumina substrate with a length of 10 mm, a width of 5 mm, and a thickness of 1 mm, and was heated at 100° C. to evaporate the organic solvent over 1 hour. Thereafter, the result was heated at 800° C. for 15 minutes to form a thin-film of silver on the alumina substrate. Subsequently, a silver sheet with a length of 10 mm, a width of 5 mm, and a thickness of 50 μm was further placed on the alumina substrate coated with the thin-film of silver. On the silver sheet were placed 5 mm-square films for forming thermal buffer layers for p-type and n-type thermoelectric materials as produced in Example 1 so that they might not overlap each other. The p-type and n-type thermoelectric materials produced in Example 1 were further separately placed on each of the films. While applying the pressure of 0.1 t perpendicularly to the surface of the alumina substrate, a heat treatment was performed at 800° C. in air for 10 hours, giving a thermoelectric element.

The thermoelectric element thus obtained was configured such that the p-type thermoelectric material and the n-type thermoelectric material were each bonded to the alumina substrate having a 50 μm-thick silver sheet via a thermal buffer layer. The thermoelectric element was shaped as shown in FIG. 1 (I), wherein the alumina substrate, to which an electrically conductive layer composed of the silver sheet was bonded, served as an electrically conductive substrate.

TABLE 17

| | Composition of | Composition of | | | | | Electrically | |
|---|---|---|---|---|---|---|---|---|
| | a p-type | an n-type | Composition of | Mixing | Composition of | Mixing | conductive | Net-like |
| | thermoelectric | thermoelectric | a thermal buffer | Ratio | a thermal buffer | Ratio | layer (Metal | or fibrous material |
| Ex. | material | material | for p-type material | A:B | for n-type material | A:B | sheet) | Shape · Position |
| 79 | Ca_{2.7}Bi_{0.3}Co₄O_{9.3} | La_{0.9}Bi_{0.1}NiO_{3.0} | A: Ca_{2.7}Bi_{0.3}Co₄O_{9.3} | 5:5 | A: La_{0.9}Bi_{0.1}NiO_{3.0} | 5:5 | Ag | None |
| | | | B: Ag | | B: Ag | | (Thickness: 50 μm) | |

1. A thermoelectric element comprising an electrically conductive substrate, a p-type thermoelectric material, and an n-type thermoelectric material,
the p-type thermoelectric material being positioned on the substrate via an electrically conductive thermal buffer material, and the n-type thermoelectric material being positioned on the substrate via an electrically conductive thermal buffer material;
wherein the thermoelectric element meets requirements (i) to (iii):
(i) the p-type thermoelectric material comprises at least one complex oxide selected from the group consisting of complex oxides represented by the formula: CaₐA¹_{b}Co_{c}A²_{d}Oₑ (wherein A¹ is one or more elements selected from the group consisting of Na, K, Li, Ti, V, Cr, Mn, Fe, Ni, Cu, Zn, Pb, Sr, Ba, Al, Bi, Y, and lanthanoids; A² is one or more elements selected from the group consisting of Ti, V, Cr, Mn, Fe, Ni, Cu, Mo, W, Nb, and Ta; 2.2≦a≦3.6; 0≦b≦0.8; 2.0≦c≦4.5; 0≦d≦2.0; and 8≦e≦10) and complex oxides represented by the formula: Bi_{f}Pb_{g}M¹ₕCoᵢM²ⱼOₖ (wherein M¹ is one or more elements selected from the group consisting of Na, K, Li, Ti, V, Cr, Mn, Fe, Ni, Cu, Zn, Pb, Ca, Sr, Ba, Al, Y, and lanthanoids; M² is one or more elements selected from the group consisting of Ti, V, Cr, Mn, Fe, Ni, Cu, Mo, W, Nb, and Ta; 1.8≦f≦2.2; 0≦g≦0.4; 1.8≦h≦2.2; 1.6≦i≦2.2; 0≦j≦0.5; and 8≦k≦10);
(ii) the n-type thermoelectric material comprises at least one complex oxide selected from the group consisting of complex oxides represented by the formula: LnₘR¹ₙNiₚR²_{q}Oᵣ (wherein Ln is one or more elements selected from the group consisting of lanthanoids; R¹ is one or more elements selected from the group consisting of Na, K, Sr, Ca, and Bi; R² is one or more elements selected from the group consisting of Ti, V, Cr, Mn, Fe, Co, Cu, Mo, W, Nb, and Ta; 0.5≦m≦1.7; 0≦n≦0.5; 0.5≦p≦1.2; 0≦q≦0.5; and 2.7≦r≦3.3) and complex oxides represented by the formula: (LnₛR³ₜ)₂NiᵤR⁴ᵥO_{w} (wherein Ln is one or more elements selected from the group consisting of lanthanoids; R³ is one or more elements selected from the group consisting of Na, K, Sr, Ca, and Bi; R⁴ is one or more elements selected from the group consisting of Ti, V, Cr, Mn, Fe, Co, Cu, Mo, W, Nb, and Ta; 0.5≦s≦1.2; 0≦t≦0.5; 0.5≦u≦1.2; 0≦v≦0.5; and 3.6≦w≦4.4); and
(iii) each electrically conductive thermal buffer material comprises an electrically conductive material having a thermal expansion coefficient between the thermal expansion coefficient of the thermoelectric material to which the thermal buffer material is bonded and the thermal expansion coefficient of the substrate.

2. A thermoelectric element according to claim 1, wherein each electrically conductive thermal buffer material comprises an oxide and a metal as effective components.

3. A thermoelectric element according to claim 2, wherein the oxide in the electrically conductive thermal buffer material comprises all or some of the constituent elements of the thermoelectric material to which the thermal buffer material is bonded.

4. A thermoelectric element according to claim 2, wherein each electrically conductive thermal buffer material comprises an oxide and a metal as effective components and has a graded composition in which the oxide/metal ratio varies gradually.

5. A thermoelectric element according to claim 1, wherein a net-like material or a fibrous material is provided at a junction between the electrically conductive substrate and each thermoelectric material.

6. A thermoelectric element according to claim 1, wherein the thermoelectric element has a thermoelectromotive force of at least 60 uv/K throughout the temperature range of 293 to 1073 K (absolute temperature).

7. A thermoelectric element according to claim 1, wherein the thermoelectric element has an electrical resistance of not more than 200 mΩ throughout the temperature range of 293 to 1073 K (absolute temperature).

8. A thermoelectric module comprising a plurality of thermoelectric elements according to claim 1, wherein the thermoelectric elements are electrically connected in series such that an unbonded end portion of a p-type thermoelectric material of one thermoelectric element is electrically connected to an unbonded end portion of an n-type thermoelectric material of another thermoelectric element.

9. A thermoelectric module according to claim 8, wherein the unbonded end portions of the thermoelectric elements are connected on a substrate.

10. A thermoelectric module according to claim 8, wherein the unbonded end portions of the thermoelectric elements are connected using an electrically conductive binder comprising an oxide and a metal.

11. A thermoelectric conversion method comprising positioning one end of a thermoelectric module according to claim 8 at a high-temperature part and positioning the other end of the module at a low-temperature part.
